(19) United States
(12) Patent Application Publication
(10) Pub. No.: US 2012/0212100 A1
(43) Pub. Date: Aug. 23, 2012

(54) PIEZOELECTRIC VIBRATION DEVICE HAVING STRUCTURE INCLUDING SELF-AMPLIFICATION FUNCTION OF VIBRATION AND ELECTRIC/ELECTRONIC DEVICE USING SAME AS VIBRATING MEANS

(76) Inventor: Han Sang Lee, Seoul (KR)

(21) Appl. No.: 13/503,901

(22) PCT Filed: Oct. 26, 2010
(86) PCT No.: PCT/KR10/07383

§ 371 Date: Apr. 25, 2012

(30) Foreign Application Priority Data
Oct. 27, 2009 (KR) 10-2009-0102090

(51) Int. Cl. H01L 41/04

(52) U.S. Cl. 310/317

(57) ABSTRACT

A piezoelectric vibrator is disclosed. A piezoelectric vibration member vibrates according to the change of polarity of applied voltage while the edge portions or a central portion shows maximum displacement with the central portion or the edge portions as an acting point of vibration, respectively. Being combined integrally with the portion of maximum displacement of the piezoelectric vibration member by a fastening member, a weight vibrates together with the vibration of the piezoelectric vibration member and amplifies the vibration. A vibration support member has one end fixed to the object to transfer vibration to and the other end combined to a specific portion of the piezoelectric vibration member, supporting the piezoelectric vibration member so as to vibrate up and down with the specific portion as an acting point of vibration.

### FIELD OF TECHNOLOGY

The present invention relates to a vibration generating device using inverse piezoelectric effect of piezoelectric material, more specifically to a piezoelectric vibrator, in which the power and the amplitude, if necessary, of vibration generated by a piezoelectric vibrating member having laminated piezoelectric material can be amplified or enhanced, and to its application.

### BACKGROUND

As well known, in piezoelectric materials, if applied with a pressure (mechanical energy) a voltage (electric energy) is generated (piezoelectric effect), and if applied with a voltage (electric energy) volume or length increases or decreases (mechanical energy) due to a pressure generated in the piezoelectric material (inverse piezoelectric effect). Especially, using the inverse piezoelectric effect, a vibrator or speaker (generating sound through vibration) can be realized.

An example of representative conventional vibrator using the inverse piezoelectric effect was disclosed in Korean Patent No. 10-0502782 titled “Piezoelectric Vibrator.” According to it, the piezoelectric vibrator has a structure, in which a plurality of piezoelectric device layers are attached to one side or both sides of a vibrating plate. With piezoelectric devices for vibrating and recovering provided separately, the vibration is generated by the recovering piezoelectric device's forceful recovering to the initial state the displacement generated by the vibrating piezoelectric device.

Various types of electronic devices such as mobile phone, pager, portable multimedia player (PMP), game machine, etc. employ vibrators widely. The vibrator used for the mobile phone, pager, etc. is used mainly as an alarm means informing arrival of phone call or set time (morning call, anniversary, etc.), or as a reaction means reacting with vibration to a user's touch. In a game machine, a mobile phone (installed with a mobile game), etc., the vibrator may be used to increase the effect in play game, for example, representing an occurrence of an event with vibration. Vibrators are being applied more and more in range and usage. In such applications, the vibrator is required to supply vibrational power strong enough to have a person recognize the vibration by touch. However, it is difficult to generate sufficient vibrational power for mobile electronic devices with the structures of piezoelectric device attached to a diaphragm as in the above Korean patent. Since the amplitude of vibrations is small and its own weight is not large, the vibrational power is not strong. The inventor of the present invention could confirm this point by testing the vibrator proposed by the patent. It was determined that such vibrators are not applicable because the vibrational power was remarkably weaker than the vibrational power generated by a coin-type vibration motor using electromagnet or solenoid-type vibrator.

### DETAILED DESCRIPTION OF INVENTION

### Problem to Solve

In order to obtain a large vibrational power, the weight of the vibration body and the vibrational displacement must be large. It is also desirable to have a large operational power. However, since there is a limit to increase the number of layers of piezoelectric device (the limit to thickness is about tens of micro meters) and to increase the thickness or size of the diaphragm for allowing vibration, it is hard to increase the weight of vibration body. Therefore, there is a limit to solving the problems through improving of piezoelectric vibration body itself. Other type of improvement is necessary. As for the operational power, since in order to provide a voltage higher than voltage of the battery of mobile electronic device as the operational power, a separate step-up circuit is needed, it is not desirable. If a battery voltage is used as the operational power, the operational power needs to be treated as a constant and then to try to improve from there.

Considering such points, an object of the present invention is to provide a piezoelectric vibrator, which can amplify the power and displacement (amplitude) of vibration generated by the piezoelectric vibration body.

Another object of the invention is to provide a piezoelectric vibrator, which can amplify the power and displacement (amplitude) of vibration generated by the piezoelectric vibration body and further amplify the displacement (amplitude) of the amplified vibration.

Still another object of the invention is to provide a piezoelectric vibrator, which has a life time extended by minimizing structural weakening of the vibration body caused by the amplification of the vibrational power and/or displacement.

Still another object of the invention is to provide an electronic device adopting the above piezoelectric vibrator as a vibration means.

### Solution to Problems

According to an aspect of the invention for solving the above problems, provided is a piezoelectric vibrator comprising: a piezoelectric vibration member generating vibration by change of applied voltage about a vibration acting point engaged to a vibration support member below; a weight integrated monolithically with the piezoelectric vibration member, vibrating with the piezoelectric vibration member by the vibration of the piezoelectric vibration member, and amplifying power and displacement of the vibration; and a vibration support member, whose one end being fixed to an object for delivering vibrational power and the other end engaging with a specific portion of the piezoelectric vibration member, for supporting the piezoelectric vibration member.

The piezoelectric vibrator may further comprise a fastening member for fastening the weight to the piezoelectric vibration member as one body. And, this fastening member may comprise an elastic fastening member for combining the weight and the piezoelectric vibration member elastically and amplifying the displacement of vibration of the piezoelectric vibration member.

In the piezoelectric vibrator, preferably the location where the weight engages with the piezoelectric vibration member is a portion where the piezoelectric vibration member gives a maximum up-and-down displacement.

In the piezoelectric vibrator, preferably a first location where the vibration support member engages the piezoelectric vibration member and a second location where the weight engages the piezoelectric vibration member are any one selected from the following four locations (from (a) to (d)): (a) the first location is both end portions of the piezoelectric vibration member in a direction of length, and the second location is a middle portion of the piezoelectric vibration member in a direction of length, (b) the first location is a middle portion of the piezoelectric vibration member in a direction of length, and the second location is both end portions of the piezoelectric vibration member in a direction of length, (c) the first location is a plurality of edge portions of the piezoelectric vibration member, and the second location is a central portion of the piezoelectric vibration member, and (d) the first location is a central portion of the piezoelectric vibration member, and the second location is a plurality of edge portions of the piezoelectric vibration member. And, preferably, in the cases of (a) or (b), the piezoelectric vibration member vibrates bending in shapes of bow and reversed bow alternatingly or alternating between a shape of bow and a flat shape without bending, and in the cases of (c) and (d), the piezoelectric vibration member vibrates bending in shapes of umbrella and flipped umbrella alternatingly or alternating between a shape of umbrella and a flat shape without bending.

In the piezoelectric vibration member, in a case that the weight is formed so as to have an area larger than the portion engaging with the piezoelectric vibration member, it is preferable that in the parts other than a portion engaging with the piezoelectric vibration member the weight is configured to stay away from the piezoelectric vibration member so as not to touch each other even during vibration.

Also, the vibration support member may be an elastic vibration support member supporting elastically the combined body of the piezoelectric vibration member and the weight and amplifying the vibration displacement of the combined body.

The piezoelectric vibrator may further comprise a housing, which receives the combined body of the piezoelectric vibration member and the weight supported by the vibration support member, and has itself fixed to one end of the vibration support member so as to receive the amplified vibration through the vibration support member.

In the piezoelectric vibrator, the vibration acting point of the piezoelectric vibration member engaging with and supported by the vibration support member is both end portions or a central portion of the piezoelectric vibration member in a direction of length when the piezoelectric vibration member is asymmetrical to have a length larger than a width, and an edge portion or a central portion of the piezoelectric vibration member when the piezoelectric vibration member is symmetrical like polygon or circle.

The piezoelectric vibration member may comprise: a substrate; piezoelectric device layers formed by laminating a single or multiple layers of piezoelectric material on one or both surfaces of the substrate; and electrode layers for applying the voltage to top and bottom surfaces of the piezoelectric device layers.

And, the weight and the piezoelectric vibration member have a top-and-bottom relation, and it is preferable to combine such that central points of both of them are aligned substantially.

On the other hand, according to another aspect of the invention for achieving the objects, a piezoelectric vibrator comprises: a piezoelectric vibration member generating vibration with a vibration acting point engaging with a vibration support member as a reference by an applied alternating voltage or intermittently applied voltage; a weight formed of material of high density and engaging with the piezoelectric vibration member, such that when the piezoelectric vibration member vibrates the weight loads its own weight at a specific portion where the displacement is largest; a fastening member fastening the weight to a specific portion of the piezoelectric vibration member and transferring the vibration of the piezoelectric vibration member to the weight, such that the weight vibrates along; and a vibration support member, whose one end is fixed to an object to which the vibration is delivered and the other end engaging with the vibration acting point of the piezoelectric vibration member and support, wherein the weight, by the vibration of the piezoelectric vibration member, vibrates up-and-down in a same direction as the direction in which the vibration support member supports the piezoelectric vibration member so as to amplify power and displacement of the vibration, and the amplified vibration is transferred to the object through the vibration support member.

Furthermore, according to still another aspect of the invention, a mobile electronic device comprises: a body; a power supply; a piezoelectric vibrator installed in a specific location of the body and generating vibration as in the above piezoelectric vibrators; and an operation controller for controlling the vibration of the piezoelectric vibration member by making the voltage needed by the piezoelectric vibrator in generating the vibration using voltage of the power supply and supplying the voltage to the piezoelectric vibrator.

### Effects of the Invention

In general, since the vibration of a single piezoelectric vibrator is weak, the piezoelectric vibrator is not adapted to use as a vibrator for a mobile electronic device such as a mobile phone, a game machine, etc. However, since the piezoelectric vibrator according to the present invention has a structure that the piezoelectric vibration member and the weight are integrated into one body and vibrate, the vibration generated by the piezoelectric vibration member is strengthened (amplified) due to the effect of the weight. A vibration which is tens or hundreds times stronger than one piezoelectric vibration member can be obtained. Therefore, it can be used as a vibrator for a mobile electronic device.

The piezoelectric vibrator of the present invention also provides a structure to add elasticity to the vibration, since an element disposed at a path where the vibration generated by the piezoelectric vibration member is delivered to the weight and/or the object to deliver the vibrational power to, that is, a fastening member and/or the vibration support member have elasticity. The vibrational displacement of the vibration strengthened by the weight gets amplified further due to the elasticity. In turn, the amplification of the displacement results in a strengthening of the vibrational power, entering a positive feedback between them.

On the other hand, the vibration body generates a maximum vibration at its resonant frequency. In case of forming the vibration body with a single piezoelectric vibrator, the resonance point where the maximum vibration takes place is close to the resonant frequency of the piezoelectric device. And, if operating the piezoelectric vibrator at the resonance point, relatively more current flows than at non-resonance points, wasting electrical power. However, in the piezoelectric vibrator according to the present invention, the piezoelectric vibrator is combined with the weight into one body to form a vibration body, and also the fastening member or elastic fastening member are combined. The factors determining the resonance point are very different, and therefore the resonance point where the piezoelectric vibrator of the invention generates maximum vibration is very different from that of a single piezoelectric vibration member. As a result, the current when the piezoelectric vibrator of the invention generates maximum vibration is much less than the current when operating at a resonance point of a single piezoelectric vibration member, decreasing the power consumed.

Also, since the weight is engaged to the piezoelectric vibrator and only at a specific portion, it is possible to make the weight thin in a form covering the piezoelectric vibration member entirely. Increasing weight does not increase the thickness much.

It is also a merit that comparing with conventional vibration motor using the principle of electrical induction the power consumption is remarkably small for an equivalent vibrational output.

### BRIEF DESCRIPTION OF DRAWINGS

FIG. 1 is a figure for describing a structure of piezoelectric vibrator: (a) and (b) showing a unimorph-type having a single piezoelectric device layer and a bimorph-type, respectively, (c) showing a bimorph-type of multiple layer structure, and (d) showing an exploded perspective view of multiple-layered piezoelectric device;

FIG. 2 is a figure for describing a principle of the bimorph-type piezoelectric vibration member's generating vibration;

FIGS. 3-5 show a rectangular piezoelectric vibrator according to a first embodiment of the invention: FIGS. 3 and 4 being exploded perspective views, and FIG. 5 an assembled front plan view;

FIGS. 6-8 are an exploded perspective view and an assembled front plan view showing a rectangular piezoelectric vibrator according to a second embodiment of the invention;

FIGS. 9 and 10 are an exploded perspective view and an assembled front plan view showing a rectangular piezoelectric vibrator according to a third embodiment of the invention;

FIGS. 11-14 show a rectangular piezoelectric vibrator according to a fourth embodiment of the invention: FIG. 11 an exploded perspective view, FIG. 12 an assembled front plan view, and FIGS. 13 and 14 perspective views showing before and after the piezoelectric vibrator is assembled into the housing;

FIGS. 15-17 are an exploded perspective view, an assembled front plan view, and a perspective view before assembling the housing, showing a rectangular piezoelectric vibrator according to a fifth embodiment of the invention;

FIG. 18 shows a variant of an elastic fastening member;

FIGS. 19 and 20 are an exploded perspective view and an assembled front plan view showing a rectangular piezoelectric vibrator according to a sixth embodiment of the invention;

FIGS. 21 and 22 are an exploded perspective view and an assembled front plan view showing a rectangular piezoelectric vibrator according to a seventh embodiment of the invention;

FIGS. 23-25 are an exploded perspective view, a front plan view, and a perspective view of assembled state showing a first embodiment of the invention of a square or quasi-square piezoelectric vibrator;

FIGS. 26-29 are an exploded perspective view, an assembled front plan view, and perspective views before and after a state assembled to a housing, showing a second embodiment of the invention of a square piezoelectric vibrator;

FIGS. 30 and 31 are an exploded perspective view and an assembled front plan view showing a third embodiment of the invention of a square piezoelectric vibrator;

FIGS. 32 to 34 are an exploded perspective view and an assembled front plan view showing a fourth embodiment of the invention of a square piezoelectric vibrator;

FIGS. 35 to 37 are an exploded perspective view and a front plan view and a perspective view of assembled state showing a first embodiment of the invention of a coin-type piezoelectric vibrator;

FIGS. 38 and 39 are an exploded perspective view and an assembled perspective view showing a second embodiment of the invention of a coin-type piezoelectric vibrator;

FIGS. 40 to 42 are an exploded perspective view and perspective views before and after a state assembled to a housing showing a third embodiment of the invention of a coin-type piezoelectric vibrator;

FIG. 43 is an exploded perspective view showing a fourth embodiment of the invention of a coin-type piezoelectric vibrator;

FIGS. 44 to 46 are an exploded perspective view and a front plan view and a perspective view of assembled state showing a fifth embodiment of the invention of a coin-type piezoelectric vibrator;

FIG. 47 is an exploded perspective view showing a piezoelectric vibrator to which a variant embodiment of an elastic vibration support member is applied; and

FIG. 48 is a diagram showing a case applying a piezoelectric vibrator to a mobile electronic device as a vibration means.

### BEST MODE OF EMBODIMENTS OF INVENTION

Hereinafter, embodiments of the invention are specified in detail referring to the attached drawings.

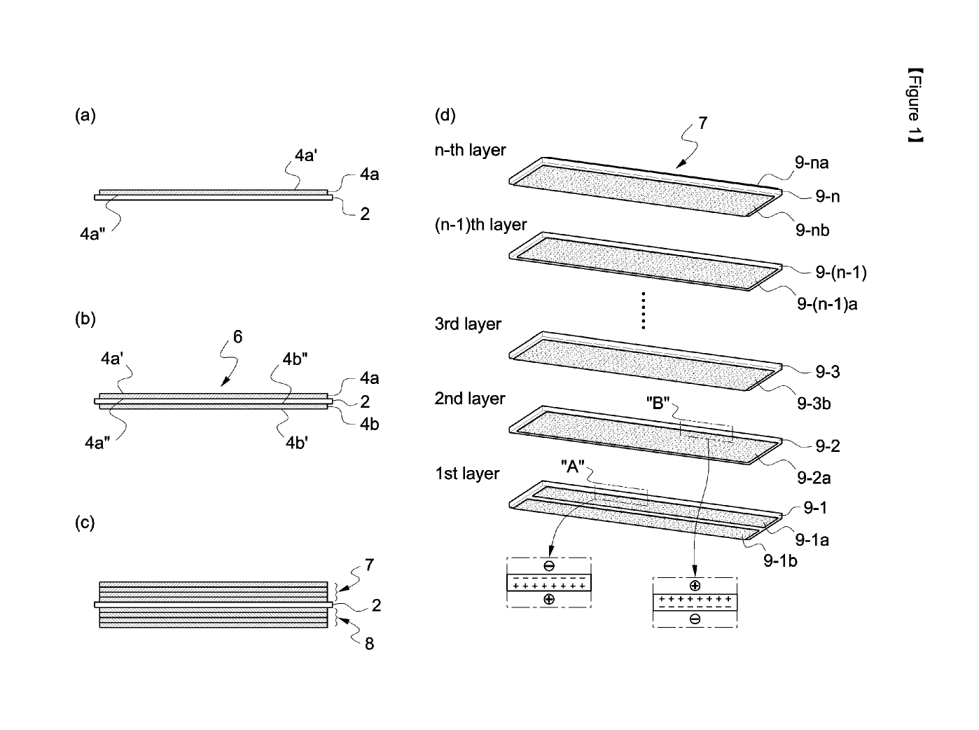

The piezoelectric vibrator comprises a piezoelectric vibration member, a vibration support member, a weight, and a fastening member. The piezoelectric vibration member is formed by laminating piezoelectric material on a substrate, and a means for generating vibration with the inverse piezoelectric effect of the piezoelectric material. The piezoelectric vibration member is fabricated in a unimorph type in which a piezoelectric device layer (4) of the piezoelectric material is laminated on a surface of both surfaces of a substrate (2), or in a bimorph type in which piezoelectric device layers (4a, 4b) are laminated on both surfaces of the substrate (2), as shown in FIG. 1 (A) and (B). On both surfaces of each piezoelectric device layer (4, 4a, 4b) are attached electrode layers (4a′, 4a″) and (4b′, 4b″). The piezoelectric device layers (4, 4a, 4b) are made of piezoelectric material. Representative example of the piezoelectric material comprises, but not limited to, piezoelectric ceramic, PZT series. The piezoelectric ceramic is weak, operated in a high voltage, and hard to set an initial point, but those defects can be overcome by multiple laminating of piezoelectric device layer.

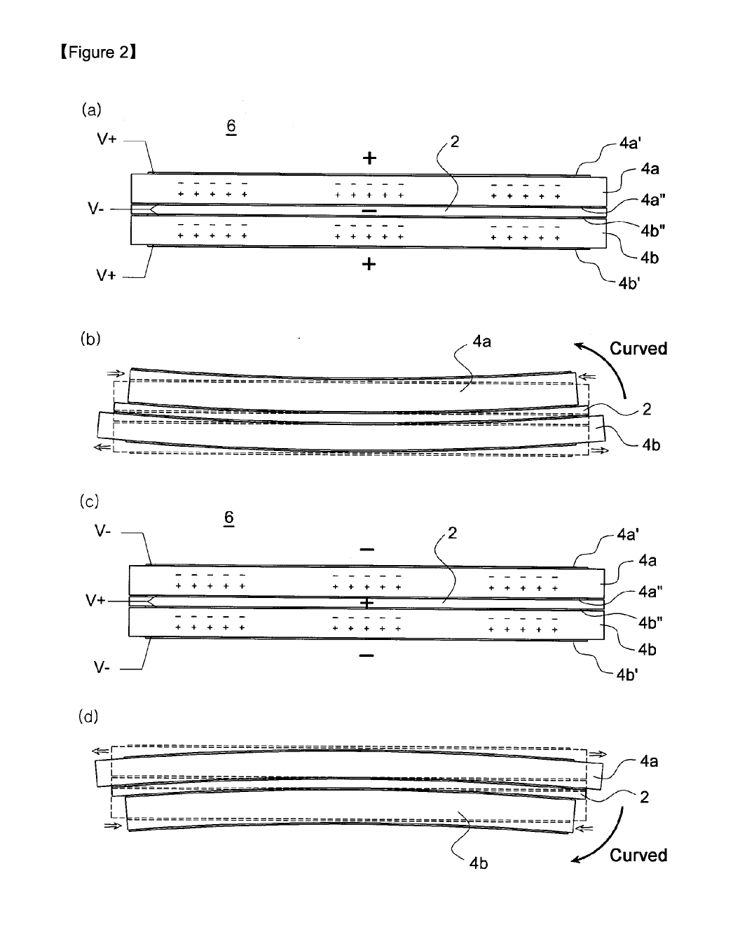

Using a single layered bimorph type piezoelectric vibration member (6) shown in FIG. 2, the principle of the piezoelectric vibration member's generating of vibration is explained briefly. Polarity is given when the piezoelectric device layer (4a, 4b) is fabricated. If the electrode layers (4a′, 4a″) and (4b′, 4b″) are deposited on both surfaces of the piezoelectric device layer (4a or 4b) made of piezoelectric material and a direct voltage is applied to the electrode layers (4a′, 4a″) and (4b′, 4b″), the positive and negative charges in the piezoelectric material are aligned in a specific direction leaving an arbitrary state, taking the polarity. Prepared piezoelectric device layers (4a, 4b) are laminated on both surfaces of the substrate (2). As shown, the piezoelectric device layers (4a, 4b) may be laminated with a same polarizing direction, or reversely (in this case, the polarity of the operational voltage must be reversed). The substrate (2) preferably comprises a material having elasticity vertically, but not horizontally. In case of using metal of good conductivity as the substrate (2), it can be used as a common electrode. To the piezoelectric device layers (4a, 4b) of both surfaces of the substrate (2) is applied an alternating operational voltage. The polarity of the operational voltage applied to each layer is set to be opposite from each other (of course, unlike the above, in case of laminating such that the polarizing direction of the piezoelectric device layers (4a, 4b) is reversed, even though the polarity of the operational voltage applied to each is same as each other, the vibration is obtained by the same principle of vibration generation below).

As shown in FIG. 2(a), to the top and bottom surfaces of the first piezoelectric device layer (4a) are applied (+) and (−) voltages respectively, while to the top and bottom surfaces of the second piezoelectric device layer (4b) are applied (−) and (+) voltages respectively. If the voltages of opposite polarity are applied, as shown in FIG. 2(b), the first piezoelectric device layer (4a) shortens its length in the horizontal direction (that is, the direction of length of the substrate (2)) by the inner pressure generated through the inverse piezoelectric effect such that the thickness gets thickened. On the contrary, the second piezoelectric device layer (4b) lengthens its length in the horizontal direction by the inner pressure generated such that the thickness gets thinned. Such changes in the first and second piezoelectric device layers (4a, 4b) take place concurrently. Thereby the piezoelectric vibration member (6) generates a bending state in which both ends are raised (a shape of ‘ [symbol] ’) as shown in FIG. 2(b).

In order to bend the other way, as shown in FIG. 2(c), if reversing the polarity of the voltage applied to the first and second piezoelectric device layers (4a, 4b), in a reverse manner as the above case, it is the first piezoelectric device layer (4a) that lengthens its length horizontally, and it is the second piezoelectric device layer (4b) that shortens its length. As a result, as shown in FIG. 2(d), the piezoelectric vibration member (6) generates a bending state in which both ends are lowered (a shape of ‘ [symbol] ’).

As described, if alternating the polarity of the operational voltage to the piezoelectric vibration member (6) by applying an alternating voltage, the piezoelectric vibration member (6) generates vibration by repeating the bending in FIG. 2(b) and the bending of FIG. 2(d) alternatingly. As the frequency of the alternating operational voltage is increased, the vibration frequency of the piezoelectric vibration member (6) is also increased.

Of course, the vibration can be generated by applying intermittent voltage, in which voltage is repeatedly supplied and disconnected. In such a case, the piezoelectric vibration member (6) repeats bending to one side and returning to a non-bending state. For example, even in a unimorph type having a piezoelectric vibration member (6) with only one first piezoelectric device layer (4a), but not the other second piezoelectric device layer (4b), a vibration can be obtained by alternating the polarity of operational voltage to the first piezoelectric device layer (4a) as well as by intermittent application of the operational voltage. If applying (+) and (−) voltages to the top and bottom surfaces of the first piezoelectric device layer (4a) respectively, the first piezoelectric device layer (4a) generates a bending with both ends raised because a pressure to decrease the horizontal length is produced. While the operational voltage is not applied to the first piezoelectric device layer (4a), the first piezoelectric device layer (4a) returns to the original state due to the elasticity of the substrate (2). By alternating these application and removal of the operational voltage (that is, intermittent application of operational voltage), the piezoelectric vibration member (6) generates a vibration.

The piezoelectric device layer may be made in a structure of a single layer as in FIGS. 1 (A) and (B), but it is preferable to make in a structure of multiple layers as in FIG. 1(C). FIG. 1(C) shows a bimorph-type multi-layered piezoelectric device layer, and each of a first piezoelectric device layer (7) and a second piezoelectric device layer (8) laminated on the top and bottom surfaces of the substrate (2) respectively are laminated by a plurality of piezoelectric device layers. If the piezoelectric device layer is multiple-layered as the above, low-voltage driving is possible compared to a single-layered piezoelectric device layer of the same thickness. For example, the number of layers of piezoelectric material is preferably from a few to 10-20. Also, a bimorph type having on both surfaces of an elastic substrate (12c) can compensate the weakness and solve the problem of initial point setting. Also, the multiple-layered structure can obtain larger vibration than a single-layered structure. Since the vibrational power and displacement of the piezoelectric vibration member depend on the structure (unimorph or bimorph), number of layers and thickness, elastic constant of substrate, etc., the designer must consider those factors.

FIG. 1(D) shows a detailed structure of the second piezoelectric device layer (8) in FIG. 1(C). The first piezoelectric device layer (7) has a structure of n (but, n is odd) layers laminated. Each layer includes piezoelectric device layers (9-1, 9-2, 9-3, . . . , 9-n) made of piezoelectric ceramic, electrode layers (9-1a, 9-1b, 9-2a, 9-2b, . . . , 9-nb) deposited on the bottom surface of each of the piezoelectric device layer, and an electrode layer (9-na) deposited on the top surface of the n-th layer (9-n) (Preferably, each layer has a same thickness, and the n-th layer in the figure is represented thicker in order to show the relation of the electrode layers on the top and bottom surfaces). On the top surface of the first layer (9-1) are disposed two electrode layers (9-1a, 9-1b) which are divided in the middle in a direction of length. The electrode layers (9-2a, . . . , 9-(n−1)a) disposed on bottom surfaces of even numbered layers above the second layer (9-2) and other the electrode layer (9-na) disposed on the top surface of the n-th layer (9-n) are connected commonly to the first electrode layer (9-1a) of the first layer (9-1). Also, the electrode layers (9-2a, . . . , 9-(n−1)a) disposed on top surfaces of odd numbered layers above the second layer (9-2) and other the electrode layer (9-na) disposed on the top surface of the n-th layer (9-n) are connected commonly to the first electrode layer (9-1a) of the first layer (9-1). In such a structure, each piezoelectric device layer is applied with direct high-voltage and polarized so as to have polarity. That is, to the first electrode layer (9-1a) and the second electrode layer (9-1b) of the first layer (9-1) are applied (+) and (−) voltages respectively. Then the odd-numbered piezoelectric device layers are polarized as in “A”, and the even-numbered piezoelectric device layers are polarized as in “B”. The second piezoelectric device layer (8) is made in the same way. And, if applying alternating operational voltage reversely to the first piezoelectric device layer (7) and the second piezoelectric device layer (8), vibration is obtained.

The piezoelectric vibration member is supported by the vibration support member and generates vibrations by the polarity change of operational voltage or intermittent supply of operational voltage. The vibration is implemented up and down according to the direction of support of the vibration support member. For example, if the vibration support member is fixed to the bottom of the object for vibration and supports the piezoelectric vibration member in a direction perpendicular to the bottom, the piezoelectric vibration member vibrates up and down along the direction perpendicular to the bottom, and if the vibration support member is fixed to a side wall of the object for vibration and supports the piezoelectric vibration member in a direction perpendicular to the side wall, the piezoelectric vibration member vibrates up and down along the direction perpendicular to the side wall.

But, the piezoelectric vibration member is light in weight, and cannot generate a vibrational power which can be used as a vibration means of a device, for example, a mobile electronic device. In order to obtain useful vibrational power, the vibration body needs to have a weight larger than a predetermined value. For such a purpose, the present invention puts a weight that is heavier to the size together with the piezoelectric vibration member. The weight may be made of material of high-density (example: tungsten or its alloy). The piezoelectric vibration member and the weight can be combined by a separate fastening member or a fastening member integrated with the piezoelectric vibration member or the weight.

The vibration support member has one end fixed to the object for vibration and other end holding and engaging with a specific portion of the piezoelectric vibration member, supporting the combined body of the weight and the piezoelectric vibration member. The combined body does not touch with the object for vibration. The specific portion of the piezoelectric vibration member which engages with the vibration support member is held by the fixed vibration support member, functioning as a vibration acting point.

The portion of the piezoelectric vibration member with which the weight engages is not the whole portion, but a specific portion. The weight is preferably engaged to a portion where a maximum displacement of vibration is generated by the piezoelectric vibration member. Since the weight works to amplify (strengthen) the vibration, the position of maximum displacement is the point of the largest acceleration, and therefore the amplification effect of vibration gets largest, too. The portion at which the piezoelectric vibration member engages with the vibration support member, that is, the combining portion of the weight and the piezoelectric vibration member may change according to the vibration acting point. For example, when the piezoelectric vibration member has an asymmetrical shape with the length longer than the width (for example, rectangular), if the vibration acting point of the piezoelectric vibration member is both ends in a direction of length, the weight is engaged to a middle portion in a direction of the piezoelectric vibration member and kept away from the rest, and contrarily if the vibration acting point is in the middle of the piezoelectric vibration member, the weight is engaged to the both ends in a direction of length of the piezoelectric vibration member and kept away from the rest. For the other example, when the piezoelectric vibration member has a symmetrical shape (for example, regular polygon or circle) with a same distance from a central point to each of the sides or edges, if the vibration acting point is the central portion of the piezoelectric vibration member, the weight is engaged to the edge portions of the piezoelectric vibration member and kept away from the rest. Contrarily, if the vibration acting points are the edge portions of the piezoelectric vibration member, the weight is engaged to the central portion of the piezoelectric vibration member and kept away from the rest. The degree of keeping away of the weight from the piezoelectric vibration member except for the combining portion is to the extent of not touching each other during the vibration.

Also, the weight is combined to the piezoelectric vibration member so as to vibrate up and down in the same direction along which the vibration support member supports the piezoelectric vibration member. In such an engagement, the mass of the weight amplifies the vibration of the piezoelectric vibration member most effectively.

If the weight is made such that its top view is substantially identical or very similar to the piezoelectric vibration member, the weight can be made thinner, improving the utility of space. If making the weight in such a way, irrespective of portions of the piezoelectric vibration member where the weight is engaged, the locations of the central points of the weight and the piezoelectric vibration member get substantially overlapped with each other, producing a stable vibration.

Furthermore, the weight is combined with the piezoelectric vibration member forming a top and a bottom, and locations of the central points of both are preferably aligned with each other substantially. If combined that way, their vibration becomes stable in alignment with the direction of supporting the vibration support member.

The weight vibrates by and along the vibration of the piezoelectric vibration member, loading its own mass on the vibration. If the mass of the weight is loaded on the piezoelectric vibration member, the mass of the vibration body results to be increased, such that comparing to the case of independent vibration of the piezoelectric vibration member the vibration frequency is decreased, but the vibrational power is increased. Especially, at a specific frequency of the alternating operational voltage, the vibrational power gets amplified (strengthened) to the maximum. The specific frequency depends on the physical specification and material property of each component such as the piezoelectric vibration member, the weight, the fastening member, the vibration support member, etc., which can be found by experiments.

When vibrating at its own resonant frequency, the vibration body generates the largest vibration (for example, the inventor performed tests on the piezoelectric vibration member while varying the frequency of operational voltage, and found that the ratio of a maximum vibrational displacement to a minimum vibrational displacement of the piezoelectric vibration member was nearly 20). When the vibration body is made of the piezoelectric vibration member without a weight, since the resonance point of the vibration body is close to the resonant frequency of the piezoelectric device layer, the value of the current flowing through the piezoelectric device layer when the piezoelectric vibration member vibrates maximally at the resonance point is relatively large. In contrast, when the vibration body is made of a combined body of the piezoelectric vibration member and the weight, since the resonance point of the vibration body is away from the resonant frequency of the piezoelectric device layer, the value of the current flowing through the piezoelectric device layer when the piezoelectric vibration member vibrates maximally at the resonance point is relatively small. According to the inventor's experiments, the current of the first case was 20 mA, while that of the second case of 220 μA, such that there was almost 90 times difference between them. Therefore, when using the weight in the vibration body, it is possible to reduce the power consumption by much.

At least one or both of the vibration support member and the fastening member may be formed so as to have elasticity. In the process of delivering the vibration, the vibrational power interacts with the elasticity of the members, and at a specific frequency of the operational power an amplification of the vibrational displacement is obtained. Also, the specific frequency depends on the physical specification and material property of each component such as the piezoelectric vibration member, the weight, the fastening member, the vibration support member, etc., which can be found by experiments.

Below are disclosed various embodiments reflecting partly or entirely the features described in the above. The following embodiments are about a piezoelectric vibration member adopting a rectangular piezoelectric vibration member as a representative case of asymmetrical shapes and a piezoelectric vibration member adopting a square and circular piezoelectric vibration member as a representative case of symmetrical shapes. The descriptions in the above about the vibration principle of piezoelectric vibration member and the amplification mechanism of the vibrational power and displacement (amplitude) apply commonly to the followings embodiments. As for the reference numerals, when a same component is adopted commonly in different embodiments, a same reference numeral is assigned.

### 1. Rectangular Piezoelectric Vibration Member

### (1) Embodiment 1-1

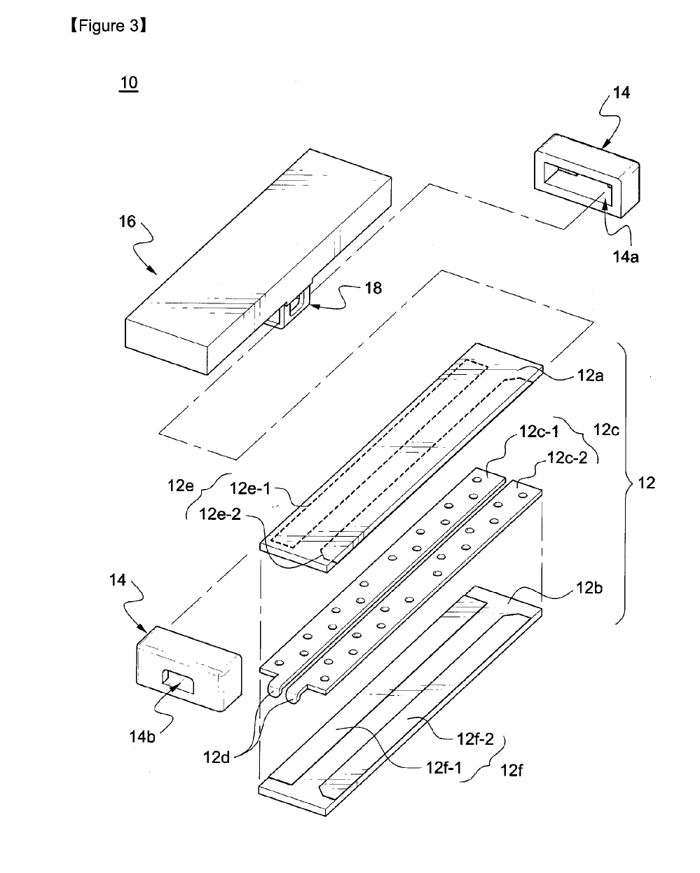

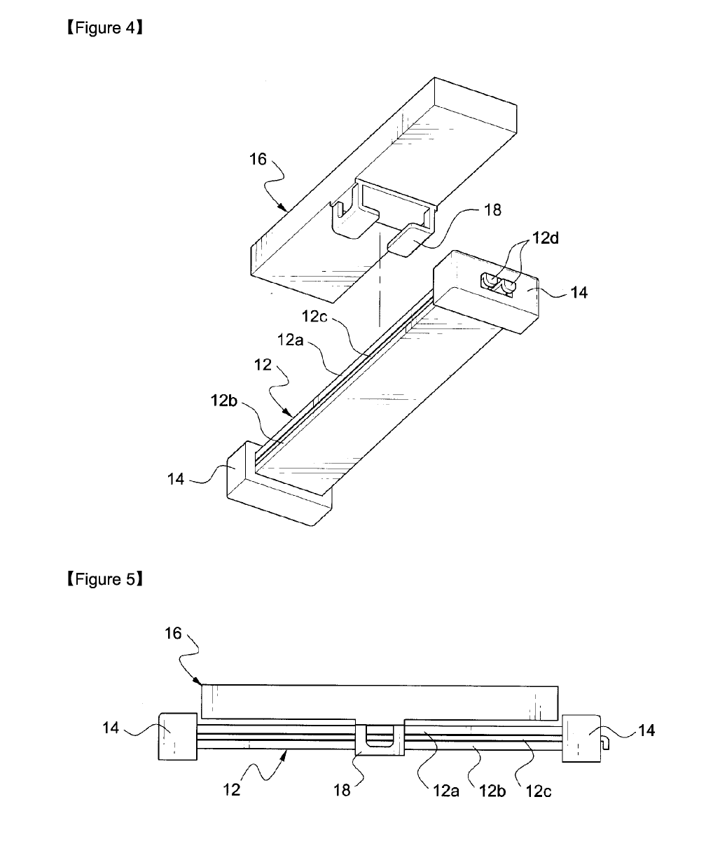

FIGS. 3-5 show a rectangular piezoelectric vibrator according to a first embodiment of the invention: FIGS. 3 and 4 being exploded perspective views, and FIG. 5 an assembled front plan view. A piezoelectric vibrator (10) comprises a piezoelectric vibration member (12), a vibration support member (14), a weight (16), and a fastening member (18). The weight (16) is combined to a middle portion of the piezoelectric vibration member (12), the vibration support member (14) is combined to both ends of the piezoelectric vibration member (12) in a direction of length.

The piezoelectric vibration member (12) is a bimorph-type piezoelectric vibration body of a rectangular plate shape, in which first and second piezoelectric device layers (12a, 12b) are deposited on both surfaces of the substrate (12c). Here, the first and second piezoelectric device layers (12a, 12b) are obtained by laminating a plurality of piezoelectric device layers shown in FIG. 1(D) (of course, it may be a single-layered structure shown in FIG. 2(A)). On a first layer of the first piezoelectric device layer (12a) are provided two electrode layers (12e-1, 12e-2), and on a first layer of the second piezoelectric device layer (12b) are provided two electrode layers (12f-1, 12f-2). The substrate (12c) keeps a structure of two laminated piezoelectric device layers (12a, 12b), and has a property of no flexibility horizontally but some flexibility vertically. Also, they are made of metal of good conductivity and formed to have two divided substrates (12c-1, 12c-2). And, if one surfaces of them contact with the two electrode layers (12e-1, 12e-2) and other surfaces contact with the two electrode layers (12f-1, 12f-2), the substrate (12c) may work as an operational power supply path. The substrate may be made of, other than metal, a PCB board, a plastic board on which electrode patterns are printed, etc. The shape may include various shapes such as a linear shape, curved shape, etc. At ends of the two substrates (12c-1, 12c-2) is provided an electrode terminal (12d) which the operational power is applied to.

The vibration support member (14) includes two cubic support blocks as a pair, and at a side surface of each vibration support member (14) is formed a receiving groove (14a) for receiving the both end portions of the piezoelectric vibration member (12). The vibration support member (14) is combined with the piezoelectric vibration member (12) by inserting both ends of the piezoelectric vibration member (12) into the receiving groove (14a). In at least one of the support blocks of the vibration support member (14) is provided a through-hole (14b) for exposing the electrode terminals (12d) externally. The vibration support member (14) is fixed to the object (not shown) for vibration. For example, the piezoelectric vibrator (10) is embedded in a housing or installed directly in a mobile electronic device without a housing. In case of installing with a housing, the object which the vibration is going to be transferred to is the housing (of course, in case of embedding in the housing and then installing in the mobile electronic device, the eventual object to transfer the vibration to will be the mobile electronic device), and in case of installing without a housing an object which the piezoelectric vibrator (10) is installed directly (for example, mobile electronic device) will be the object which the piezoelectric vibrator (10) transfers the vibration to.

In the figure the weight (16) is shown as a rectangular parallelopiped resembling the piezoelectric vibration member (12), but there is no limit to its shape as long as it can load its own mass on the piezoelectric vibration member (12). On a bottom surface of the weight (16) is provided the fastening member (18) integrally with the weight (16). The piezoelectric vibration member (12) is inserted in the fastening member (18), and the weight (16) engages as if riding on the middle portion of the piezoelectric vibration member (12). That is, the mass of the weight (16) is loaded entirely on the middle portion of the piezoelectric vibration member (12). Also, the fastening member (18) keeps the piezoelectric vibration member (12) and the weight (16) from contact each other even during the vibration except for the middle portions (engaging portions).

The vibration is generated as follows. If an alternating operational voltage is applied to the through-hole (12d), when viewed from the front side in FIG. 5, the piezoelectric vibration member (12) repeats alternatingly bending in a shape of [symbol] (the horizontal length of the first piezoelectric device layer (12a) is shortened and the horizontal length of the second piezoelectric device layer (12b) is lengthened) and bending in a shape of [symbol] (the horizontal length of the first piezoelectric device layer (12a) is lengthened and the horizontal length of the second piezoelectric device layer (12b) is shortened), so as to generate vibration.

Since both end portions of the piezoelectric vibration member (12) are held by the vibration support member (14) fixed to the object to transfer vibration to, when the piezoelectric vibration member (12) vibrates, its both end portions become acting points and its middle portion vibrates showing maximum up-and-down displacement. That is, the vibrating piezoelectric vibration member (12) repeats alternatingly so called bow shape (‘ [symbol] ’) and inverse bow shape (‘ [symbol] ’).

Since the entire mass of the weight (16) is applied to the middle portion of the piezoelectric vibration member (12), while the piezoelectric vibration member (12) vibrates that way, the weight (16) vibrates along showing maximum up-and-down displacement. By adding the weight (16), the frequency of the vibration generated by the piezoelectric vibration member (12) is decreased, and the vibration is amplified. That is, the power and displacement of the vibration get larger. The amplified vibration is transferred again to both end portions from the middle portion of the piezoelectric vibration member (12), and then delivered to the object to transfer vibration to through the vibration support member (14).

### (2) Embodiment 1-2

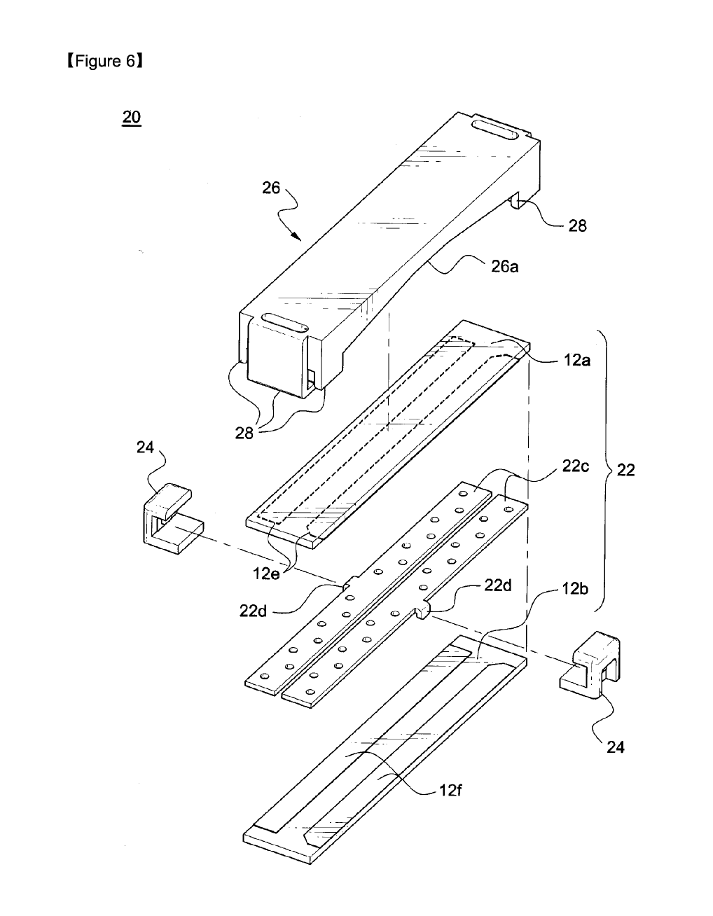

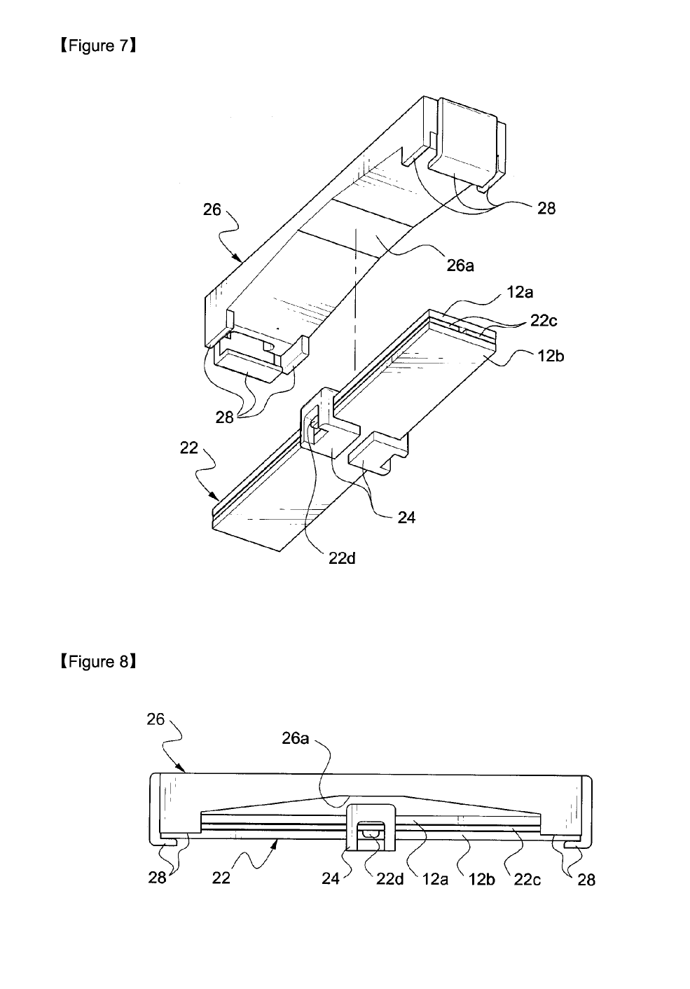

FIGS. 6-8 are an exploded perspective view and an assembled front plan view showing a rectangular piezoelectric vibrator according to a second embodiment of the invention. A piezoelectric vibrator (20) comprises a piezoelectric vibration member (22), a vibration support member (24), a weight (26), and a fastening holder (28). The kinds of these components are same as in the piezoelectric vibrator (10) according to the Embodiment 1-1, but the engagement relations among them are slightly different. The weight (26) is combined with both end portions of the piezoelectric vibration member (22) in a direction of length, and the vibration support member (24) is combined with a middle portion of the piezoelectric vibration member (22).

More specifically, the piezoelectric vibration member (22) has substantially the same structure as the piezoelectric vibration member (12) according to the Embodiment 1-1. That is, it is a bimorph type in which the first and second piezoelectric device layers (12a, 12b) are deposited on both surfaces of the two substrates (22c). However, they are different in that the location of an electrode terminal (22d) is in the middle portion of the piezoelectric vibration member (22). The first and second embodiments are same in that the locations of the electrode terminals are located at a portion of least vibration in order to minimize disconnection of circuit, that is, at the portion engaging with the vibration support member (24).

The vibration support member (24) is a pair of holders having a shape of ‘U’, and combined to the piezoelectric vibration member (22) by being inserted with and enclosing the middle portion of the piezoelectric vibration member (22). The bottom of the vibration support member (24) is fixed to the object to transfer vibration to, and the piezoelectric vibration member (22) is kept away from the object so as not to touch and then supported.

The weight (26) has a mass heavy enough for the vibration amplification, and at both ends are provided fastening holders (28) for holding and engaging with both ends of the piezoelectric vibration member (22). The piezoelectric vibration member (22) engages the fastening holder (28) by inserting its both ends into the fastening holder (28). In order to prevent contact with the vibration support member (24) even during vibration, the weight (26) is formed with a rounded bottom surface (26a) facing the piezoelectric vibration member (22).

The vibration is generated if applying an alternating operational voltage to the piezoelectric vibration member (22). Since the middle portion of the piezoelectric vibration member (22) in a direction of length is fixed by the vibration support member (24), the piezoelectric vibration member (22) generates vibration by swing right half and left half up and down about the middle portion as the acting point. At that moment, both ends of the piezoelectric vibration member (22) show maximum displacement. Also in this case, the vibration is repeating alternatingly of bow shape and inverse-bow shape. By such a vibration, the weight (26) engaged to the both ends of the piezoelectric vibration member (22) vibrates along up and down (vertically), amplifying the vibration. And, the amplified vibration is transferred again to the vibration support member (24) engaged to the middle portion through both ends of the piezoelectric vibration member (22), and further delivered to the object to transfer vibration to.

Comparing to the Embodiment 1-1, in the case of piezoelectric vibrator (10) according to Embodiment 1-1, the middle portion of the piezoelectric vibration member (12) in a direction of length becomes an acting point of vibration and the middle portion vibrates with maximum up-and-down (vertical) displacement, while in the case of piezoelectric vibrator (20) according to Embodiment 1-2, the middle portion of the piezoelectric vibration member (22) in a direction of length becomes an acting point of vibration and the right half and the left half swing up and down to generate vibration, and the right and left half end portions show maximum displacement.

### (3) Embodiment 1-3

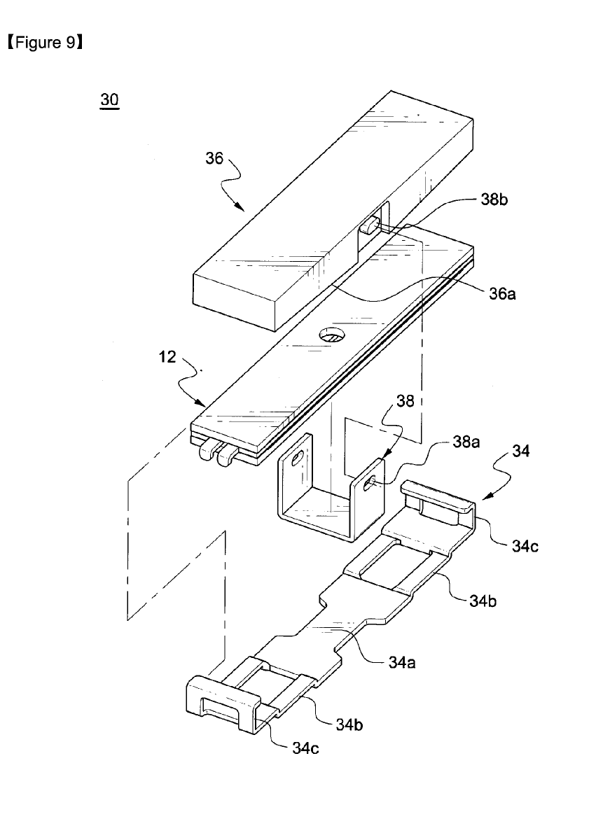

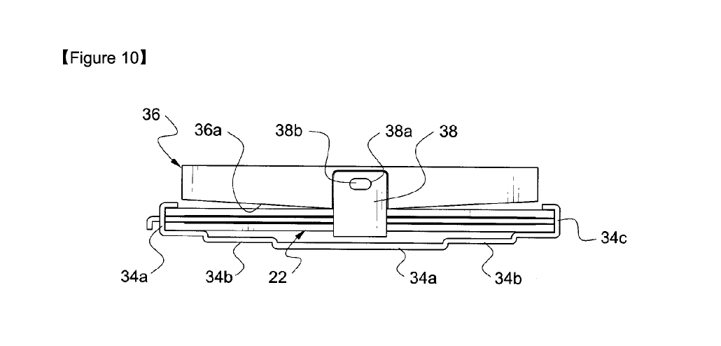

FIGS. 9 and 10 are an exploded perspective view and an assembled front plan view showing a rectangular piezoelectric vibrator according to a third embodiment of the invention. This piezoelectric vibrator (30) also, as in the two previous embodiments, includes four components, the piezoelectric vibration member (12), a vibration support member (34), a weight (36), and a fastening holder (38), but there are differences in that the vibration support member (34) has elasticity and the fastening holder (38) and the weight (36) are not integrated. The weight (36) is combined to a middle portion of the piezoelectric vibration member (12) through the fastening holder (38), and the vibration support member (34) is engaged to both ends of the piezoelectric vibration member (12) in a direction of length.

More specifically, the piezoelectric vibration member (12) is same as that in Embodiment 1-1. The weight (36) has a shape of quasi-parallelopipe, and the thickness decreases as goes from a middle portion toward both ends. And, on both side surfaces is provided a fastening protrusion (38b). The fastening holder (38) is a squared U-shaped member, which includes a bottom portion and two vertical members disposed vertically at both ends of the bottom portion. Enclosing the middle portion of the piezoelectric vibration member (12), the two vertical portions engage the fastening protrusion (38b) of the weight (36). By this, to the middle portion of the piezoelectric vibration member (12) is engaged the weight (36) integrally, and its mass is loaded entirely on the middle portion of the piezoelectric vibration member (12). The fastening holder (38) also prevents the weight (36) and the piezoelectric vibration member (12) from contacting each other except for the combining portion, so as to provide a space for vibration. Of course, instead of the fastening holder (38) which is not integrated with the weight (36), the fastening member (18) which is integrated with the weight (16), as in Embodiment 1-1 may be employed.

The vibration support member (34) comprises a fixing member (34a) fixed to the object to transfer vibration to, and an elastic support member, which extends to and engages with both ends (vibration acting point) of the piezoelectric vibration member (12), supports the combined body of the piezoelectric vibration member (12) and the vibration support member (34), and amplifies the vibrational displacement of the combined body. The elastic support member comprises elastic arms (34b) having an upward step on the fixing member (34a) and extending to both directions of right and left, and fastening holders (34c) connected to the end of the both elastic arms (34b). To these fastening holders (34c) are inserted and engaged both ends of the piezoelectric vibration member (12). Also, the middle part of the piezoelectric vibration member (12) is kept away so as not to contact with the elastic arm (34b) even by vertical vibration. By such an engagement, the vibration support member (34) holds both end portions of the piezoelectric vibration member (12) in a direction of length and engaged with them, elastically supporting the combined body of the piezoelectric vibration member (12) and the weight (36).

Vibration of the piezoelectric vibrator (30) is obtained as follows. If an alternating operational voltage is applied to the piezoelectric vibration member (12), the piezoelectric vibration member (12) vibrates. At that moment, the vibration acting point of the piezoelectric vibration member (12) is both ends thereof which are held by the fastening holder (34c) of the vibration support member (34). With the acting point as a reference the middle portion of the piezoelectric vibration member (12) vibrates up and down showing maximum displacement. At that moment, the weight (36) also vibrates vertically with the middle portion of the piezoelectric vibration member (12), amplifying the vibrational power and displacement. Such an amplified vibration is further amplified in amplitude by the elasticity of the vibration support member (34). The amplified vibration is transferred to the object to transfer vibration to through the vibration support member (34).

### (4) Embodiment 1-4

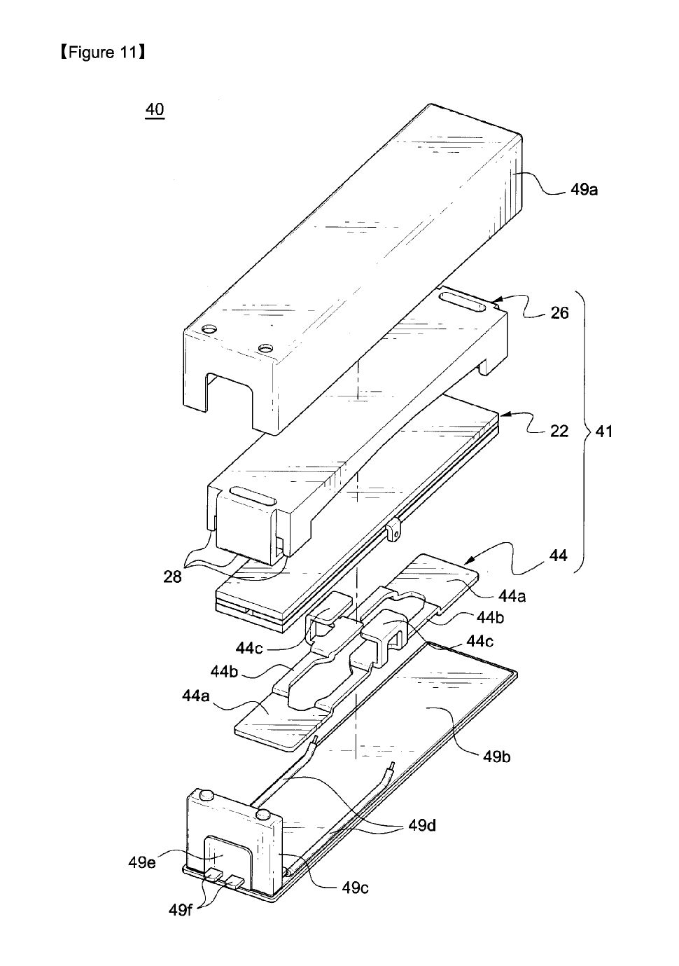

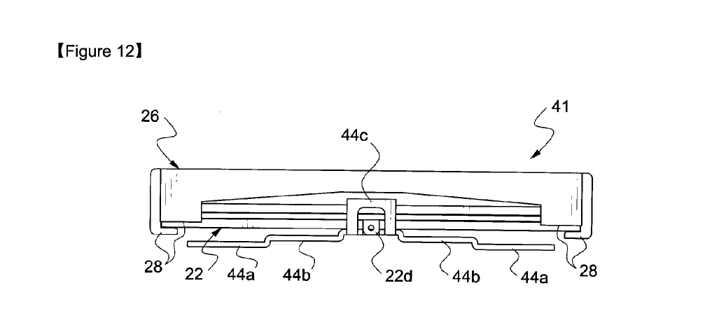

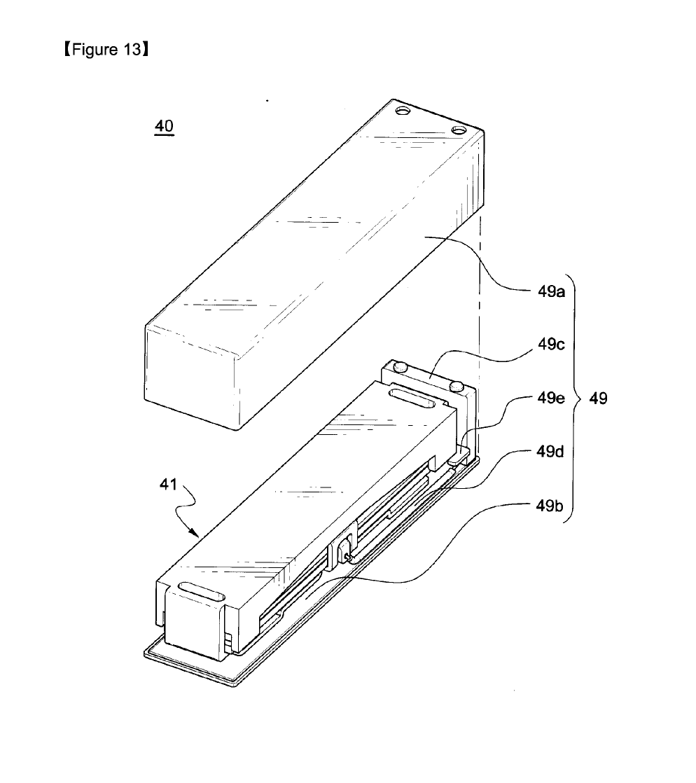

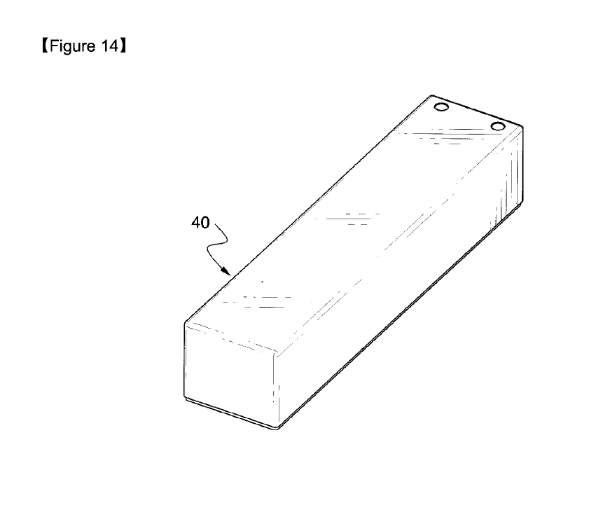

FIGS. 11-14 show a rectangular piezoelectric vibrator according to a fourth embodiment of the invention: FIG. 11 an exploded perspective view, FIG. 12 an assembled front plan view, and FIGS. 13 and 14 perspective views showing before and after the piezoelectric vibrator (41) is assembled into the housing. The piezoelectric vibrator module (40) is the piezoelectric vibrator (41) embedded in a housing (49). The piezoelectric vibrator (41), as in the previous embodiments, comprises a piezoelectric vibration member (22), a vibration support member (44), a weight (26), and a fastening holder (28). The piezoelectric vibration member (22), the weight (26), and the fastening holder (28) of the piezoelectric vibrator (41) are same as those in the second embodiment, and only the vibration support member (44) is new.

The vibration support member (44) comprises two fixing members (44a) fixed on a floor plate (49b), which is the object to transfer vibration to. Also, it comprises an elastic support member comprising an elastic bridge (44b) having a step on top and connecting the two fixing members (44a) and a fastening holder (44c) provided above the middle point of the elastic bridge (44b). The weight (26) is combined to both ends of the piezoelectric vibration member (22) in a direction of length. The fastening holder (44c) is inserted and engaged to the middle portion of the piezoelectric vibrator (41) in a direction of length. By this engagement, the vibration support member (44) supports elastically the combined body of the piezoelectric vibration member (22) and the weight (26).

The housing (49) comprises a cover (49a), a floor plate (49b), and a side wall (49c). A hole is provided in a position where the cover (49a) meets the side wall (49c) of the floor plate (49b), and the cover (49a) is combined to the floor plate (49b) through screws. The assembled housing (49) provides a space of a parallelopipe shape for receiving the piezoelectric vibrator (41) inside. On the side wall (49c) is provided an electrode terminal (49e) connecting a wire (49d) for supplying operational voltage of the piezoelectric vibration member (42). The wire (49d) is connected to the electrode terminal (22d) of the piezoelectric vibration member (22). If the electrode terminal (22d) is provided on an end portion of the piezoelectric vibration member (22) in a direction of length, the electrode terminal (22d) is exposed externally. Fixing the fixing member (44a) to the floor plate (49b) of the housing (49), the combined body of the piezoelectric vibrator (41) is received inside the housing (49). The piezoelectric vibrator module (40) received inside the housing (49) is installed in a specific position of a mobile electronic device.

According to such structure, the vibration acting point of the piezoelectric vibration member (22) is the middle portion engaged to the vibration support member (44). Therefore, the piezoelectric vibration member (22) vibrating by the alternating operational voltage vibrates up and down by swing the right and left half thereof with the middle portion as the acting point. At that moment, both ends of the piezoelectric vibration member (22) show maximum displacement. The vibration vibrates the weight (26) engaged to both ends thereof and gets amplified, and such an amplified vibration is transferred to the vibration support member (44) positioned at the vibration acting point through the piezoelectric vibration member (22), the vibration support member (44) vibrating along. At that moment, the elasticity of the vibration support member (44) acts on the vibration and amplifies the vibrational displacement further. The vibration generated by the piezoelectric vibration member (22) is amplified in power and displacement by the weight (26) and the vibration support member (44), and delivered to the object to transfer vibration to.

### (6) Embodiment 1-5

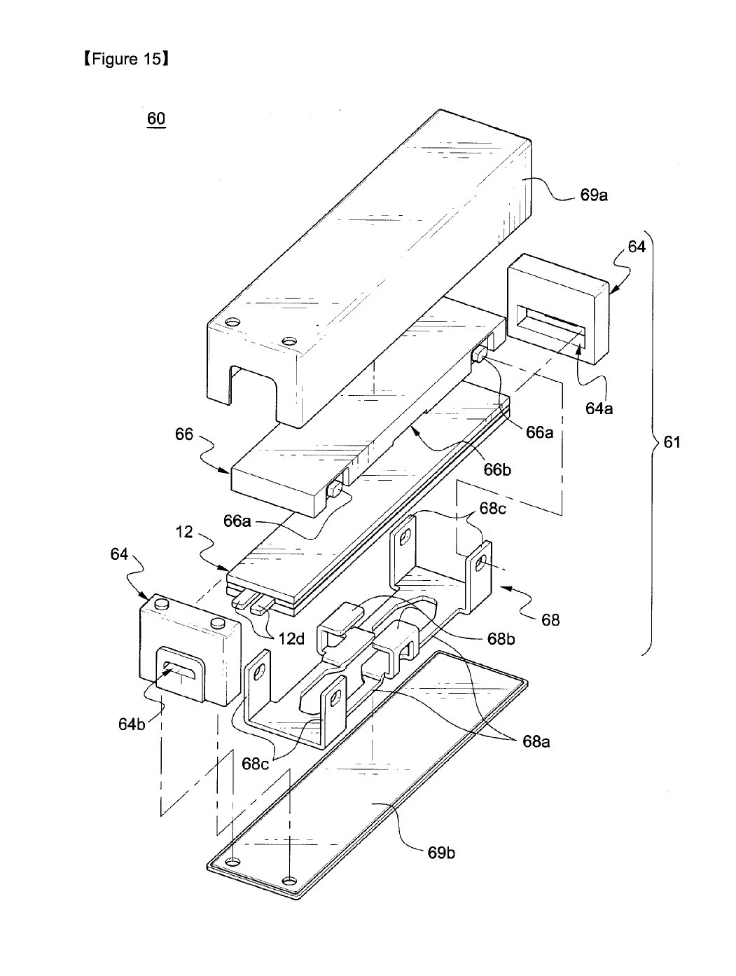

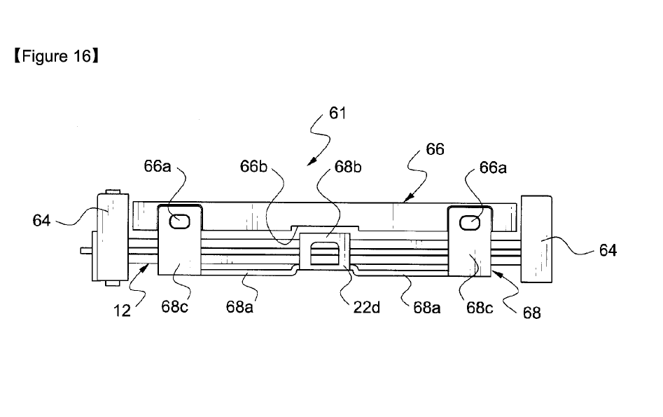

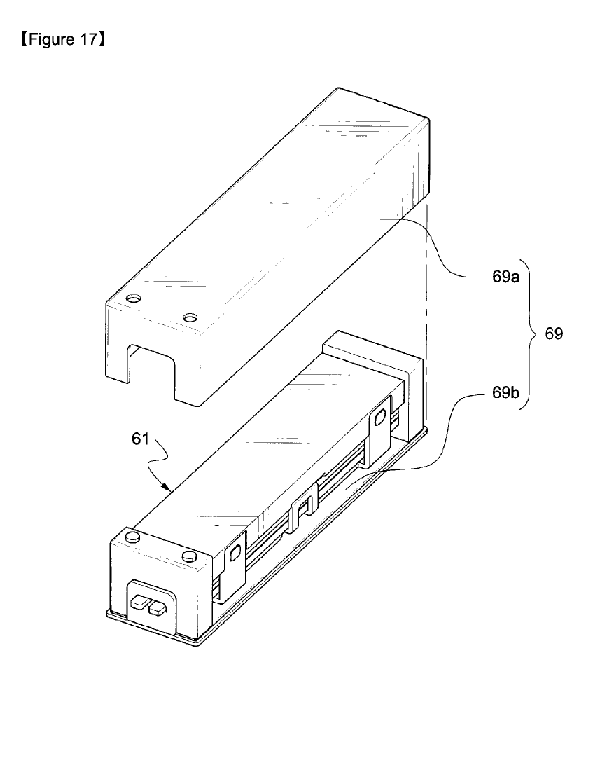

FIGS. 15-17 are an exploded perspective view showing a rectangular piezoelectric vibrator module (60), an assembled front plan view showing a rectangular piezoelectric vibrator (61), and a perspective view before assembling the housing showing a rectangular piezoelectric vibrator module (60) according to a fifth embodiment of the invention.

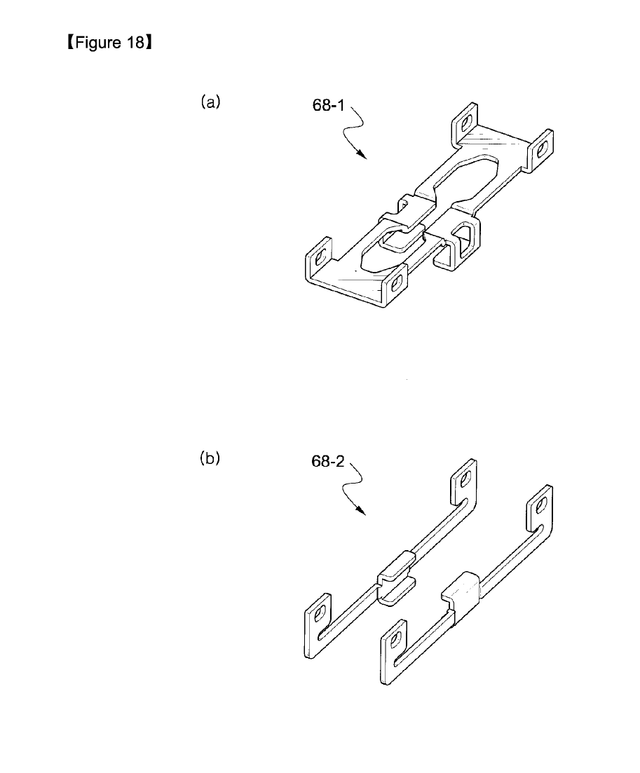

More specifically, vibration support members (64) are comprised of two cubic blocks, and on a facing surface of the two vibration support members (64) is provided a groove (64a) for receiving an end portion of the piezoelectric vibration member (12) respectively. Especially, in any one of the vibration support members (64) is provided a hole (64b) for exposing the electrode terminals (12d) of the piezoelectric vibration member (12). An elastic fastening member (68) comprises an elastic base portion (68a) extended by a specific length in a direction of length, a fastening holder (68b) provided above from the middle position of the elastic base portion (68a), and four fasteners (68c) extending perpendicularly from four corners of the elastic base portion (68a). The fastening member (68), as shown in FIG. 18, may be changed to other structures (68-1, 68-2). Both ends of the piezoelectric vibration member (12) in a direction of length are inserted and engaged to the groove (64a) of the two vibration support members (64) respectively, the middle portion of the piezoelectric vibration member (12) in a direction of length is inserted and engaged to the fastening holder (68b) of the fastening member (68). A weight (66) provides four fastening protrusions (66a) on both side surfaces of the parallelepiped body. To the fastening protrusions (66a) are engaged the four fasteners (68c) of the fastening member (68). The weight (66) is kept away from the piezoelectric vibration member (12) everywhere except for the combining portion. Also, in the middle of the bottom surface of the weight (66) is provided a groove (66b), so as to prevent from contacting directly with the fastening holder (68b). By this engagement, the mass of the weight (66) is loaded on the middle portion of the piezoelectric vibration member (12) in a direction of length. The assembled piezoelectric vibrator (61) is embedded in the housing (69). The bottom surface of the vibration support member (64) is fixed to the floor member (69b) of the housing (69).

The vibration mechanism of the piezoelectric vibrator module (60) is as follows. That is, by applying of an alternating operational voltage, both ends of the piezoelectric vibration member (12) fixed by the vibration support member (64) become an acting point of vibration, and the middle portion of the piezoelectric vibration member (12) in a direction of length vibrates up and down. The vibration is transferred to the weight (66) through the fastening member (68), and the weight (66) vibrates along. In the processes, the vibration generated by the piezoelectric vibration member (12) is amplified in power and displacement by the mass of the weight (66) and the elasticity of the fastening member (68). Such an amplified vibration is transferred to the vibration support member (64) engaged to the vibrational acting point through the piezoelectric vibration member (12), and further transferred to the housing (69). If embedding the piezoelectric vibrator module (60) in a mobile phone (not shown), the vibration is delivered to the mobile phone.

### (7) Embodiment 1-6

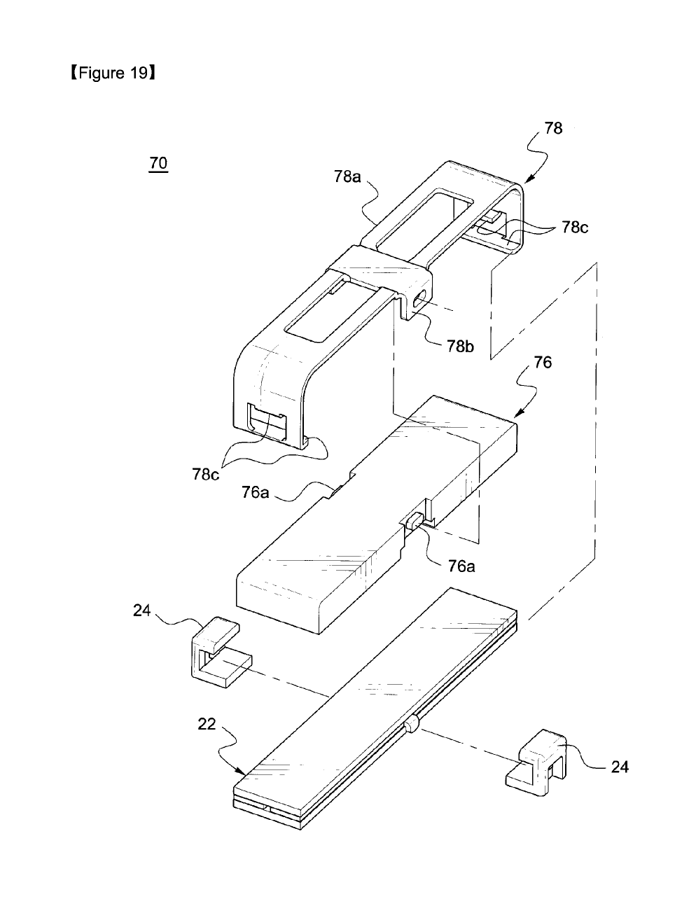

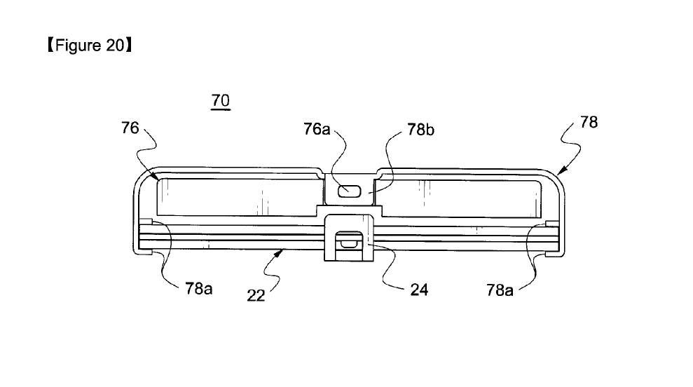

FIGS. 19 and 20 are an exploded perspective view and an assembled front plan view showing a rectangular piezoelectric vibrator (70) according to a sixth embodiment of the invention. On both side surfaces of a parallelepiped weight (76) are provided fastening protrusions (76a). The fastening member (78) comprises a pair of fasteners (78b) provided below the middle portion of the base portion (78a) extending in a direction of length of the weight (76), and a pair of fastening holders (78c) provided below both ends of the base portion (78a). The fasteners (78b) of the fastening member (78) are engaged to the fastening protrusions (76a) of the weight (76), and the fastening holders (78c) are inserted and engaged both ends of the piezoelectric vibration member (22) in a direction of length. By this, the weight (76) is integrated with the piezoelectric vibration member (22), and the mass of the weight (76) is loaded on both ends of the piezoelectric vibration member (22). Two U-shaped vibration support members are inserted and engaged to the middle portion of the piezoelectric vibration member (22) in a direction of length.

By these structures, when an alternating operational voltage is applied, the piezoelectric vibration member (22) vibrates up and down with the point engaging with the vibration support member (24) as a vibrational acting point by swing the right and left end portions. The vibration on both ends of the piezoelectric vibration member (22) showing maximum displacement gets amplified in power and displacement while being transferred to the weight (76) through the fastening member (78). The amplified vibration goes through the piezoelectric vibration member (22) again, and is delivered to the object to transfer vibration to through the vibration support member (24).

### (8) Embodiment 1-7

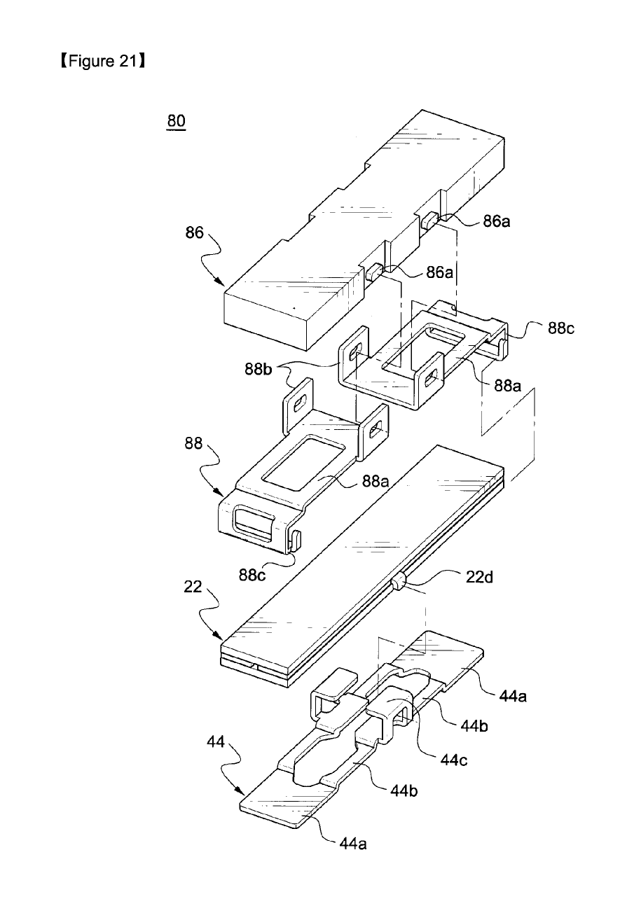

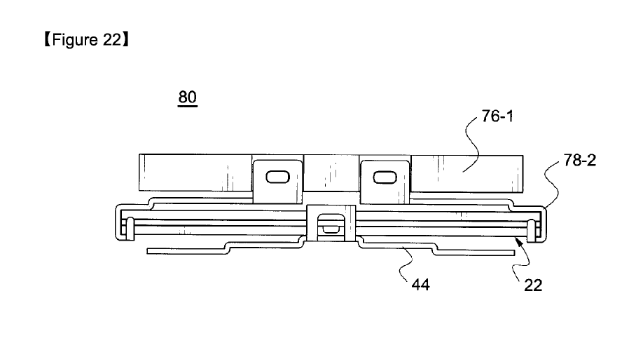

FIGS. 21 and 22 are an exploded perspective view and an assembled front plan view showing a rectangular piezoelectric vibrator (80) according to a seventh embodiment of the invention. This embodiment has a feature that both of a fastening member and a vibration support member have elasticity.

More specifically, on both side surfaces of the parallelepiped weight (86) are provided two pairs of fastening protrusions (86a). The fastening member (88) includes two fastening members having the same structure, and one fastening member comprises a base portion (88a) extending in a direction of length, a pair of fasteners (88b) extending perpendicularly from one end thereof, and a fastening holder (88c) provided below from the other end of the base portion (88a). One of the two fastening members (88) is inserted to and engaged with the left end of the piezoelectric vibration member (22) and the pair of fastening protrusions (86a) of the weight (86), and the other one is inserted to and engaged with the right end of the piezoelectric vibration member (22) and the other pair of fastening protrusions (86a) of the weight (86). The fastening holder (44c) of the vibration support member (44) is inserted and engaged to the middle portion of the piezoelectric vibration member (22) in a direction of length.

If an alternating operational voltage is applied, the middle portion of the piezoelectric vibration member (22) in a direction of length becomes an acting point of vibration, and the piezoelectric vibration member (22) vibrates with maximum displacement by both end portions. The vibration is transferred to the weight (86) through the fastening member (88), and is amplified in the power and displacement of vibration. The amplified vibration is delivered again to the vibration support member (44) through piezoelectric vibration member (22). In that process, once more, the displacement of vibration is amplified. The vibration going through the amplification process is delivered to the object to transfer vibration to.

### 2. Square Piezoelectric Vibrator

Next, if the shape of the piezoelectric vibration member is asymmetrical about a central point (from the central point, a length in a direction is relatively longer than a length in another direction) like rectangular or substantially rectangular as in the previous embodiments, the acting point of vibration is preferably a middle portion thereof in a direction of length or both ends thereof. In contrast, if the shape of the piezoelectric vibration member is symmetrical about a central point (in cases of polygon, a length from the central point to each sides is substantially same. Circle is symmetrical too.) like regular polygon or substantially regular polygon or circular, the acting point of vibration is preferably a central point thereof or its edge portions thereof.

The various embodiments below correspond to the latter cases. First of all, as a representative case of regular polygon, the case of square piezoelectric vibration member is described.

### (1) Embodiment 2-1

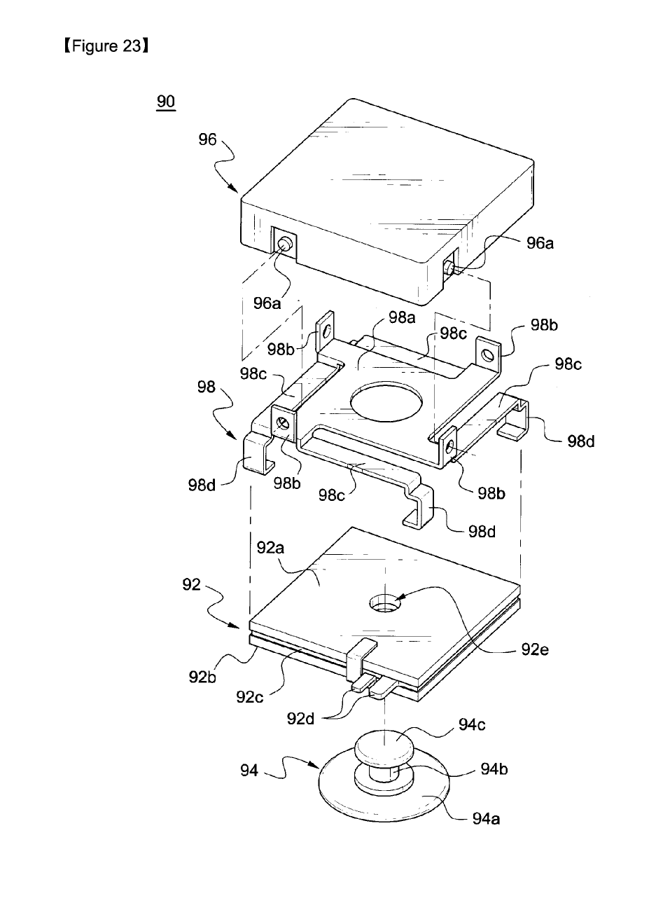

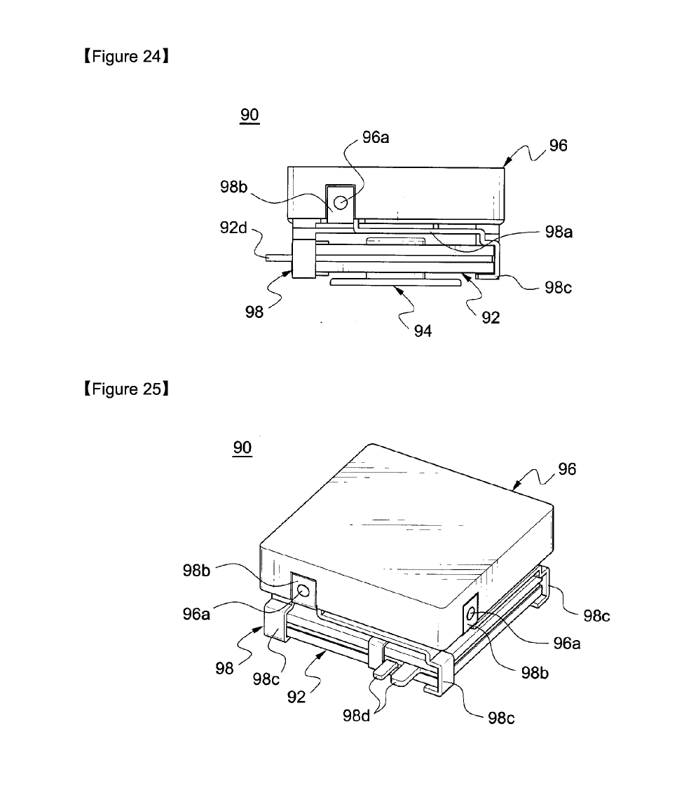

FIGS. 23-25 are an exploded perspective view, a front plan view, and a perspective view of assembled state showing a first embodiment of the invention of a square or quasi-square piezoelectric vibrator. The piezoelectric vibrator (90) comprises a piezoelectric vibration member (92), a vibration support member (94), a weight (96), and an elastic fastening member (98). The weight (96) is integrally combined to edge portions of the piezoelectric vibration member (92), and the vibration support member (94) is engaged to the center of the piezoelectric vibration member (92). For such engagements, each component has the following structure.

First of all, the piezoelectric vibration member (92) includes a first piezoelectric device layer (92a) and a second piezoelectric device layer (92b) deposited on top and bottom surfaces of the substrate (92c) respectively. Not shown, but on the bottom and top surfaces of the first piezoelectric device layer (92a) are disposed electrode layers, and to these electrode layers are connected two electrode terminals (92d) respectively. Also on top and bottom surfaces of the second piezoelectric device layer (92b) are disposed the electrode layers, and the two electrode terminal (92d) are connected to the electrode layers. Also in case of multiple layers of the first and second piezoelectric device layers (92a, 92b), as in the same type as described in FIG. 1(D), the electrode layers may be disposed such that the operational voltage may be applied to each layer. At a central portion of the piezoelectric vibration member (92) is provided a fastening hole (92e). The operational voltage is applied through two electrode terminals (92d).

The vibration support member (94) comprises a supporting circular plate (94a) fixed to the object to transfer vibration to, and a fastening axle (94b) extending perpendicularly from the center of the supporting circular plate (94a) and inserted and engaged to the fastening hole (92e). At a top end of the fastening axle (94b) is preferably provided an axle head (94c) for preventing the piezoelectric vibration member (92) from dislocate.

The weight (96) is made of material of high density. It can be made in a substantially square shape like the piezoelectric vibration member (92), but since the shape is independent from the function, it may be made in other shapes. This applies to the other embodiments. On four side surfaces of the weight (96) are provided the fastening protrusions (96a).

The elastic fastening member (98) comprises an approximately square substrate portion (98a), four fastening portions (98b) extending upward perpendicularly from the four corners thereof, four elastic arms (98c) extending horizontally from the four corners of the substrate portion (98a), and four fastening holder (98d) provided downward from ends of the elastic arm (98c). The fastening protrusions (96a) is engaged with the fastening portion (98b) of the elastic fastening member (98), and four locations around edge portions of the piezoelectric vibration member (92) are inserted and engaged to the fastening holder (98d) of the elastic fastening member (98). The elastic fastening member (98) positions the weight (96) above the piezoelectric vibration member (92) and combines the two elastically, such that the mass of the weight (96) is loaded on the edge portions of the piezoelectric vibration member (92).

The vibration mechanism of the piezoelectric vibrator (90) is as follows. If an operational voltage is applied to the electrode terminal (92d), since the central portion is fixed to the vibration support member (94), the piezoelectric vibration member (92) vibrates up and down while the edge portions produce maximum displacements with the central portion as an acting point of vibration. In similitudes, the vibration support member (94) is a handle axle of an umbrella and the piezoelectric vibration member (92) is a canopy of the umbrella, and the vibration is generated by repeating an opened shape of umbrella (‘umbrella shape’) and a flipped shape of umbrella (‘flipped umbrella shape’) alternatingly. The vibration is transferred to the weight (96) through the elastic fastening member (98) and the weight (96) engaged to the edge portion of the piezoelectric vibration member (92) vibrates together up and down with maximum displacement. In such a process, the vibration of the piezoelectric vibration member (92) is amplified in the power and displacement of vibration by the mass of the weight (96). At the same time, the displacement of the amplified vibration is further amplified due to the function of the elasticity of the elastic fastening member (98). The amplified vibration goes through the elastic fastening member (98) and the piezoelectric vibration member (92) in order again and is delivered to the vibration support member (94), and finally to the object to transfer vibration to through the supporting circular plate (94a).

### (2) Embodiment 2-2

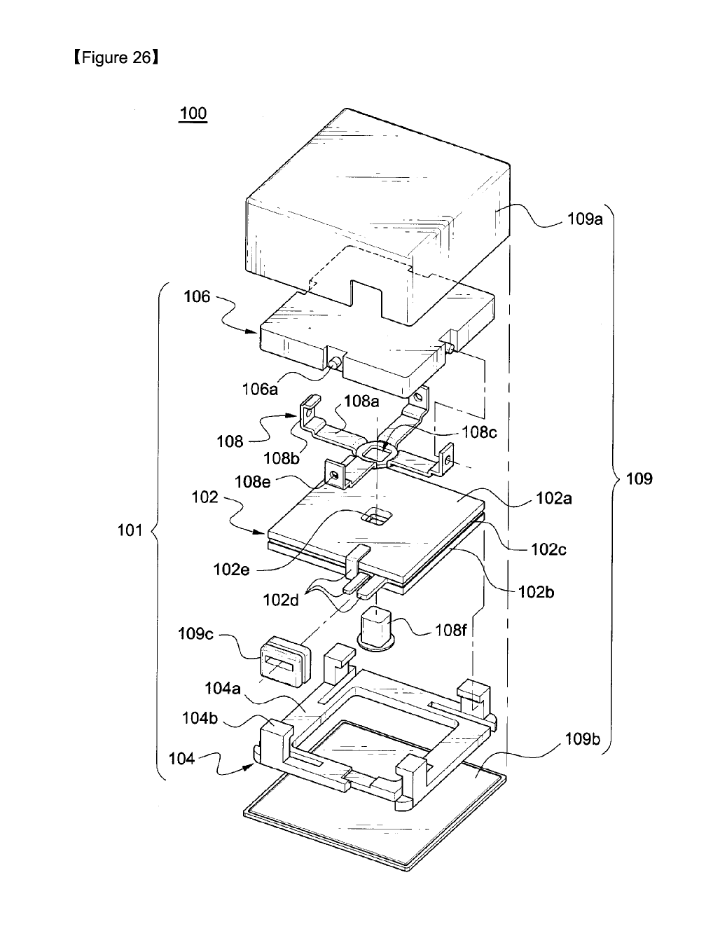

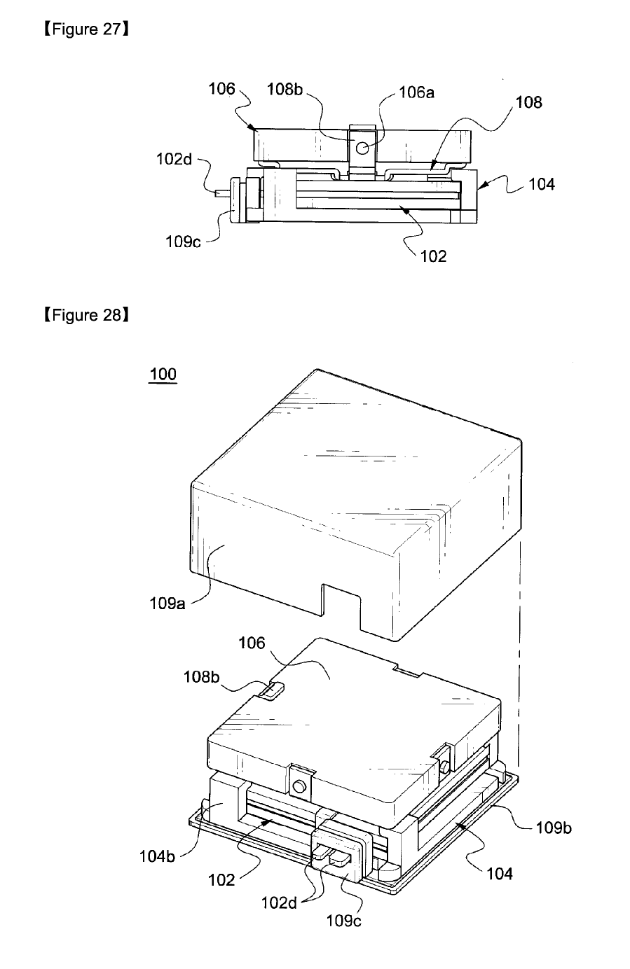

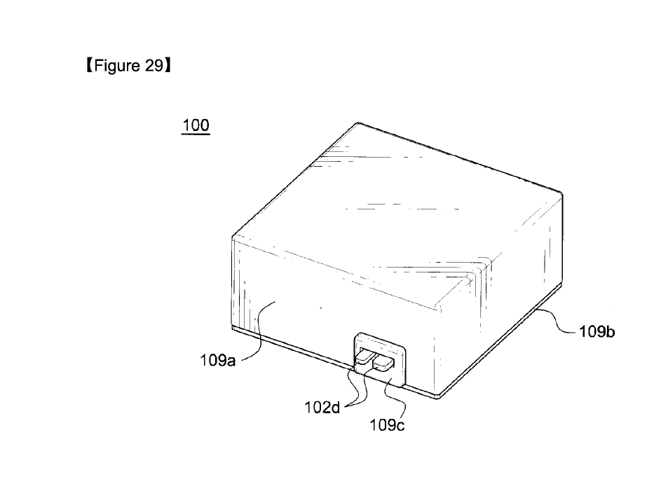

FIGS. 26-29 are an exploded perspective view, an assembled front plan view, and a perspective view before and after a state assembled to a housing (109), showing a second embodiment of the invention of a square piezoelectric vibrator (101).

More specifically, the piezoelectric vibration member (102) has the same structure as the piezoelectric vibration member (92) described in the previous embodiment except that the fastening hole (102b) is square. The vibration support member (104) has a structure in which the fastening holders (104b) are provided upward at four corners of the base portion (104a) having a shape of rectangular boxing ring. To the four edges of the piezoelectric vibration member (102) are inserted and engaged the fastening holders (104b). The weight (106) made of material of high density has a plan view of a substantial square, and at four sides are provided the fastening protrusions (106a). The four elastic arms (108a) of the elastic fastening member (108) meet together at a central point forming a cross, and at the end portions of each elastic arm (108a) is provided upward the fastening holder (108b). Also, in the crossing points of the elastic arms (108a) is provided a fastening hole (108c). The elastic fastening member (108) also includes a fastening pin (108d). The fastening holders (108b) of the elastic fastening member (108) are engaged to the fastening protrusions (106a) of the weight (106), and the fastening pin (108d) is inserted to an engaging hole (102e) of the piezoelectric vibration member (102) upward from below and proceeds upto the fastening hole (108c) of the elastic fastening member (108) so as to be inserted and engaged. By this, the weight (106) is engaged to the central portion of the piezoelectric vibration member (102) elastically. In this assembled piezoelectric vibrator (101), the bottom surface of the base portion (104a) of the vibration support member (104) is fixed to the floor portion (109b) of the housing (109). In such a state, it is embedded in the housing (109) by covering the housing cover (109a). At that moment, the electrode terminal (102d) is exposed through a terminal protection member (109c).

According to a piezoelectric vibrator module (100) having such structures, if an alternating operational voltage is applied to the piezoelectric vibration member (102) through the electrode terminal (102d), the piezoelectric vibration member (102) held by the fastening holder (104b) of the vibration support member (104) vibrates while its edge portions become an acting point of vibration and its central portion shows the maximum displacement up and down. That is, in this case, the vibration is generated while the piezoelectric vibration member (102) repeats the umbrella shape and the flipped umbrella shape alternatingly. The vibration is transferred to the weight (106) through the elastic fastening member (108), amplifying the power and displacement of vibration, and the amplified vibration is again delivered to the vibration support member (104) along the piezoelectric vibration member (102), and then to the housing (109).

### (3) Embodiment 2-3

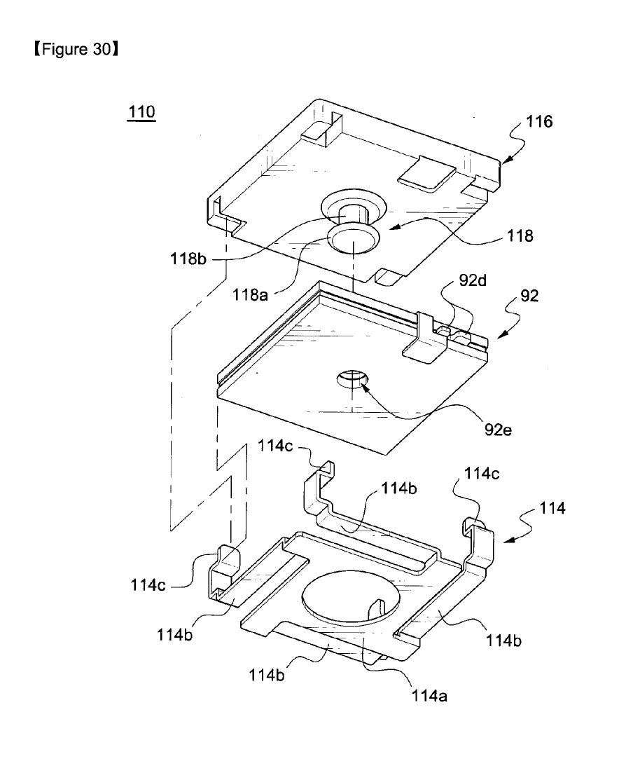

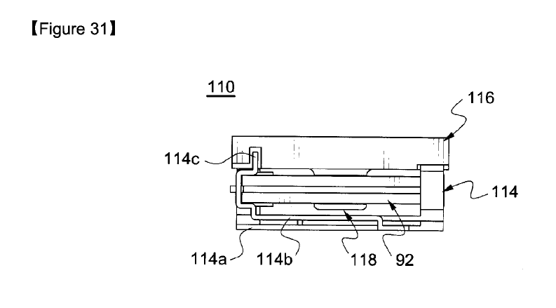

FIGS. 30 and 31 are an exploded perspective view and an assembled front plan view showing a third embodiment of the invention of a square piezoelectric vibrator (110).

To the center of bottom surface of substantially squared cube weight (116) is connected downward integrally a fastening member (118). The fastening member (118) includes a fastening axle (118b) and an axle head (118a) connected to an end portion of the fastening axle (118b). The fastening hole (92e) of the piezoelectric vibration member (92) is engaged to the fastening member (118). An elastic vibration support member (114) comprises a base portion (114a) of the substantial square shape fixed to the object to transfer vibration to, four elastic arms (114b) extending with step upward from four corners of the base portion (114a), and four fastening holders (114c) provided upward at end portions of the elastic arms (114b). The four fastening holders (114c) are inserted and engaged to the four corners of the piezoelectric vibration member (92).

According to the piezoelectric vibrator (110) having the above structures, by the alternating operational voltage, the piezoelectric vibration member (92) vibrates up and down while the edge portions fixed to the vibration support member (114) become acting points of vibration and the central portion shows the maximum displacement. Also the weight (116) vibrates up and down, strengthening the vibration. The strengthened vibration is amplified in displacement while transferred to the vibration support member (114), and delivered to the object to transfer vibration to.

### (4) Embodiment 2-4

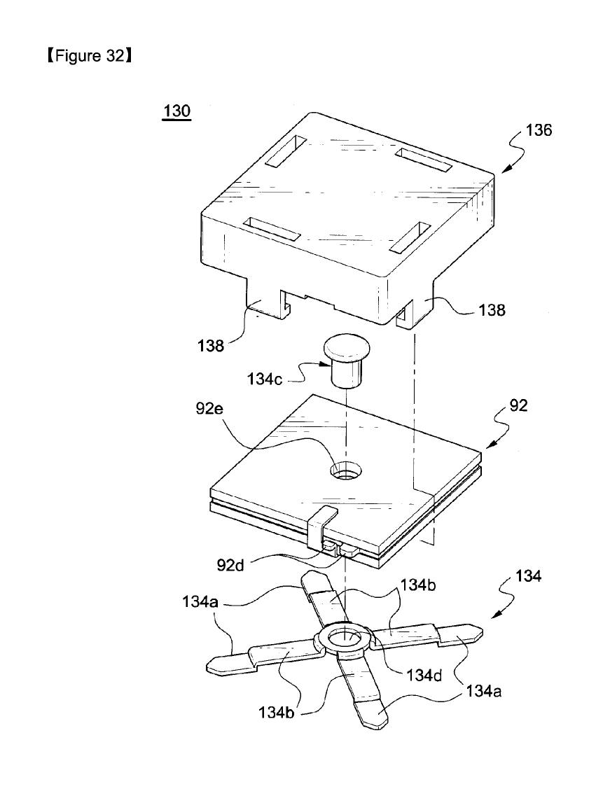

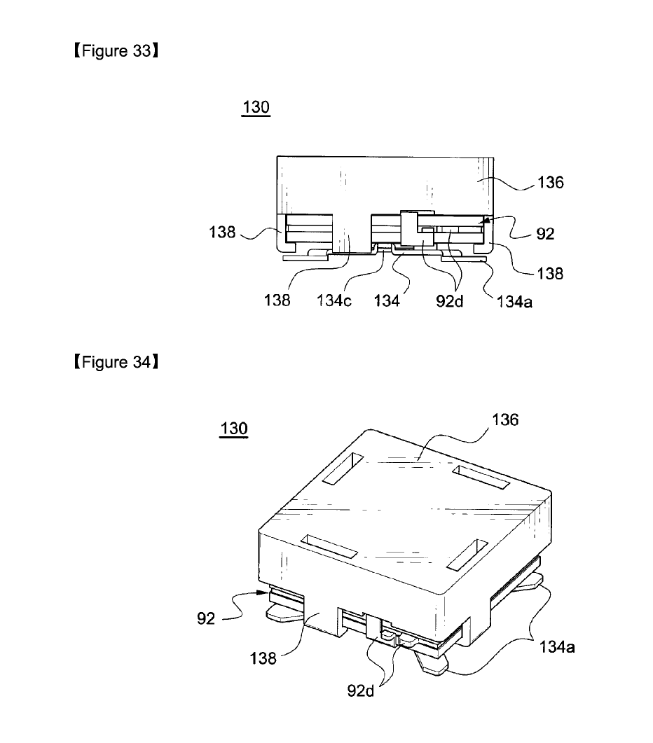

FIGS. 32 to 34 are an exploded perspective view and an assembled front plan view showing a fourth embodiment of the invention of a square piezoelectric vibrator. A weight (136) made of material of high density has four fastening members (138) extending downward from the four sides of the substantial squared cube integrally. The vibration support member (134) includes four elastic support portions which are connected to form a cross, and in the middle of it is provided a fastening hole (134d). Each elastic support portion comprises a fixing portion (134a) fixed to the object to transfer vibration to and an elastic arm (134b) extending horizontally with a step upward from one side of the vibration support member (134). The vibration support member (134) includes a fastening axle (134c), too. The fastening axle (134c) is inserted to the fastening hole (92e) of the piezoelectric vibration member (92) from the top toward the bottom, extends upto the fastening hole (134d) of the vibration support member (134), and inserted and engaged. By this, the central portion of the piezoelectric vibration member (92) becomes the acting point of vibration. Four positions on the edge portions of the piezoelectric vibration member (92) are inserted and engaged to the fastening member (138). By this, the mass of the weight (136) is loaded on the edge portions of the piezoelectric vibration member (92).

The vibration mechanism of the piezoelectric vibrator (130) may be guessed from the previous descriptions. That is, the piezoelectric vibration member (92) vibrates while the edge portions vibrates up and down with the center as an acting point of vibration, and the weight (136) vibrates along, amplifying the vibration. The amplified vibration goes through amplification process by the vibration support member (134) and is transferred to object to transfer vibration to.

### 3. Coin-Type Piezoelectric Vibrator

### (1) Embodiment 3-1

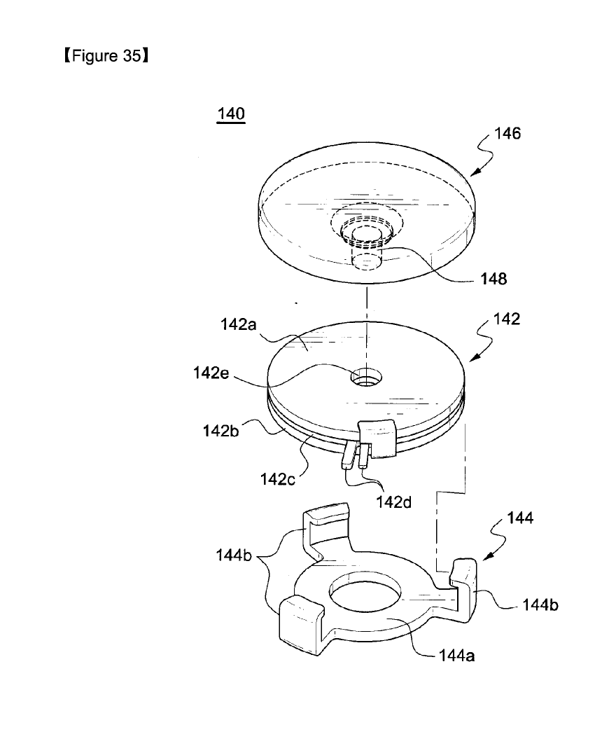

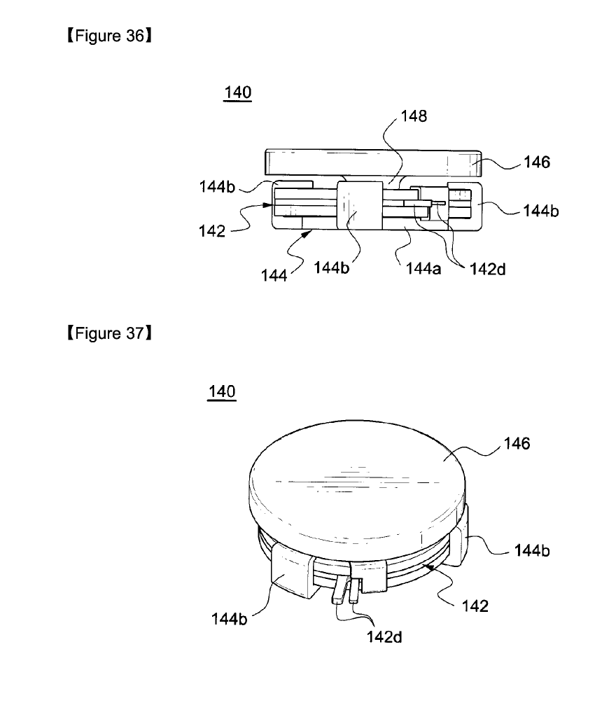

FIGS. 35 to 37 are an exploded perspective view and a front plan view and a perspective view of assembled state showing a first embodiment of the invention of a coin-type piezoelectric vibrator. The coin-type piezoelectric vibrator (140), as in the previous embodiments, comprises a piezoelectric vibration member (142), a vibration support member (144), a weight (146), and a fastening member (148).

The piezoelectric vibration member (142) is substantially the same as the piezoelectric vibration member (92) of square sided cube shape described in the above except that it is coin-type. That is, on top and bottom surfaces of the circular piezoelectric vibration member (142) are laminated the first piezoelectric device layer (142a) and the second piezoelectric device layer (142b) respectively, forming a coin-type shape overall. Of course, not shown, electrode layers are disposed such that the operational voltage is applied to top and bottom surface of each piezoelectric vibration member (142) and each layers of the second piezoelectric device layer (142b). And, the electrode layers are connected to the electrode terminal (142d). Also the weight (146) is made of material of high density in a shape of coin-type, and in the central portion extends downward a fastening axle for the fastening member (148). The fastening member (148) is inserted and engaged to the fastening hole (142e) formed in the center of the piezoelectric vibration member (142). The vibration support member (144) comprises a circular base portion (144a) and a plurality of fastening holders (144b) provided integrally upward in a couple of locations of its edge portions. The edge portions of the piezoelectric vibration member (142) are inserted and engaged to the fastening holders (144b). The bottom surface of the base portion (144a) is fixed to the object to transfer vibration to.

The vibration mechanism of the piezoelectric vibrator (140) is as follows. By the applied alternating operational voltage, the piezoelectric vibration member (142) vibrates while the central portion shows the maximum displacement with the edge portion as an acting point. That is, it vibrates while repeating the shape of umbrella and the shape of flipped umbrella. By the vibration the weight (146) vibrates along with a maximum displacement. In such a vibration process, the power and displacement of vibration are amplified, and the amplified vibration is transferred to the object to transfer vibration to through the piezoelectric vibration member (142) and the vibration support member (144).

### (2) Embodiment 3-2

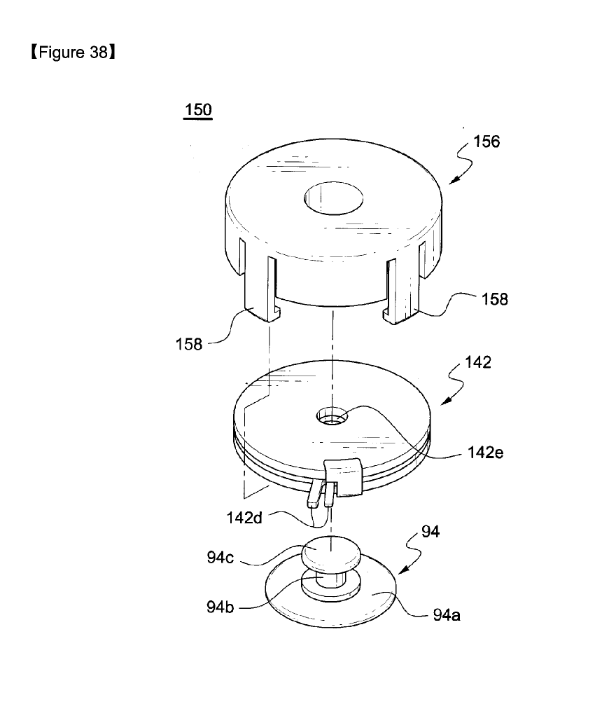

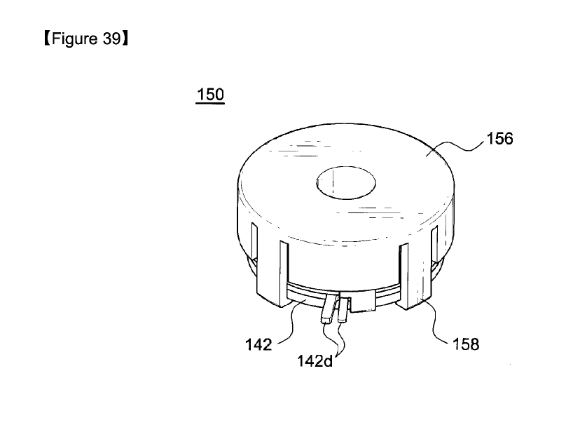

FIGS. 38 and 39 are an exploded perspective view and an assembled perspective view showing a second embodiment of the invention of a coin-type piezoelectric vibrator. The components of the piezoelectric vibrator (150) are same as in the previous embodiments. A weight (156) is combined to the edge portions of the piezoelectric vibration member (142), and the vibration support member (94) is combined to the central portion of the piezoelectric vibration member (142).

The piezoelectric vibration member (142) is same as in the previous embodiment, and the vibration support member (94) is also same as the first embodiment of the rectangular piezoelectric vibrator shown in FIGS. 23-25. To the fastening hole (142e) of the piezoelectric vibration member (142) is inserted and engaged to the fastening axle (94b) of the vibration support member (94). The weight (156) has a coin-type body, and the fastening member (158) extends integrally downward from the edge portions of the body of the weight (156) with the end portion finished to be bent almost perpendicularly. The edge portions of the piezoelectric vibration member (142) are inserted and engaged to the fastening member (158). The combined body of the piezoelectric vibration member (142) and the weight (156) is supported by the vibration support member (94).

If an alternating operational voltage is applied through the electrode terminals (142d), the piezoelectric vibration member (142) vibrates up and down while the edge portions show the maximum displacement with the vibration support member (94) positioned in the central portion of the piezoelectric vibration member (142) as an acting point of vibration. Also in this case, the piezoelectric vibration member (142) repeats the shape of umbrella and the shape of flipped umbrella alternatingly. By that, the weight (156) engaged to the edge portion of the piezoelectric vibration member (142) vibrates up and down, amplifying the vibrational power. The amplified vibrational power is delivered to the object to transfer vibration to through the piezoelectric vibration member (142) and the vibration support member (94).

### (3) Embodiment 3-3

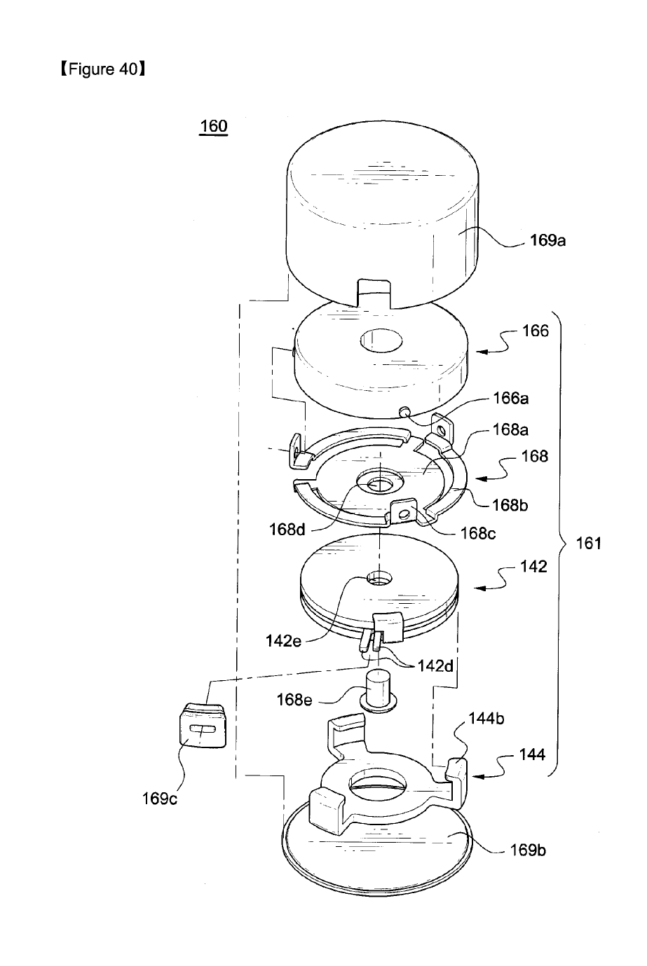

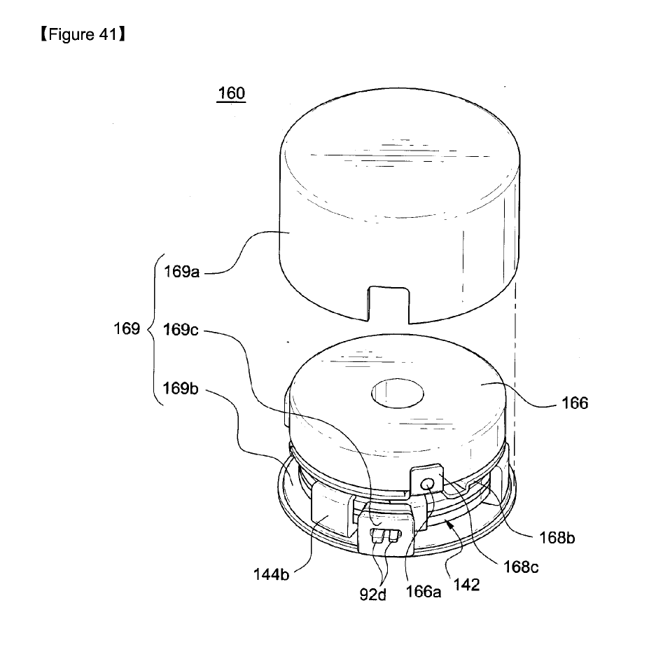

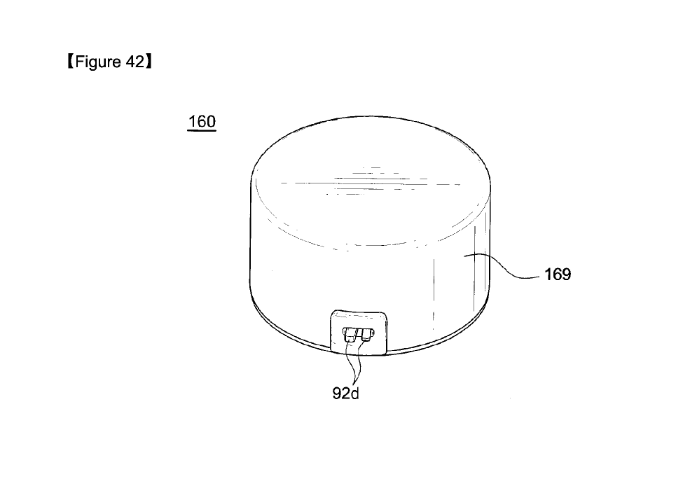

FIGS. 40 to 42 are an exploded perspective view and perspective views before and after a state assembled to a housing showing a third embodiment of the invention of a coin-type piezoelectric vibrator.

The vibration support member (144) and the piezoelectric vibration member (142) are same as shown in FIGS. 35-37. Therefore, the edge portion of the piezoelectric vibration member (142) is inserted and engaged to the fastening holders (144b) of the vibration support member (144). The weight (166) made of material of high density are formed with three fastening protrusions (166a) on the side surface of its coin type body. An elastic fastening member (168) comprises a circular base portion (168a) provided at the center with a fastening hole (168d), elastic arms (168b) extending by a specific length along the circumferential direction with a step above three edge portions, and fasteners (168c) connected upward from the end of the elastic arms (168b). Also, the elastic fastening member (168) comprises a fastening axle (168e). To these fasteners (168c) are engaged the fastening protrusions (166a) of the weight (166), the fastening axle (168e) is inserted to the fastening hole (142e) provided at the center of the piezoelectric vibration member (142) upward from below, and inserted and engaged upto the fastening hole (168d) of the elastic fastening member (168), such that the elastic fastening member (168) combines elastically the weight (166) and the piezoelectric vibration member (142). After assembling the piezoelectric vibrator (161), the bottom surface of the vibration support member (144) is fixed to the housing floor (169b), and the housing cover (169a) is put in place. And, the electrode terminals (142d) of the piezoelectric vibration member (142) are exposed externally through the housing (169). The piezoelectric vibrator module (160) assembled in the housing (169) is installed in a mobile electronic device.

The vibration mechanism of the piezoelectric vibrator module (160) assembled in the housing (169) is as follows. If an alternating operational voltage is applied, the piezoelectric vibration member (142) vibrates up and down while the central portion shows the maximum displacement with the edge portion held and fixed to the vibration support member (144) as an acting point of vibration. The vibration is transferred to the weight (166) through the housing (169), and the weight (166) vibrates together. In that process, the elasticity of the elastic fastening member (168) and the mass of the weight (166) work, amplifying the power and displacement of vibration. The amplified vibration goes through the piezoelectric vibration member (142) again and the vibration support member (144) and transferred to the housing (169), vibrating the mobile electronic device.

### (4) Embodiment 3-4

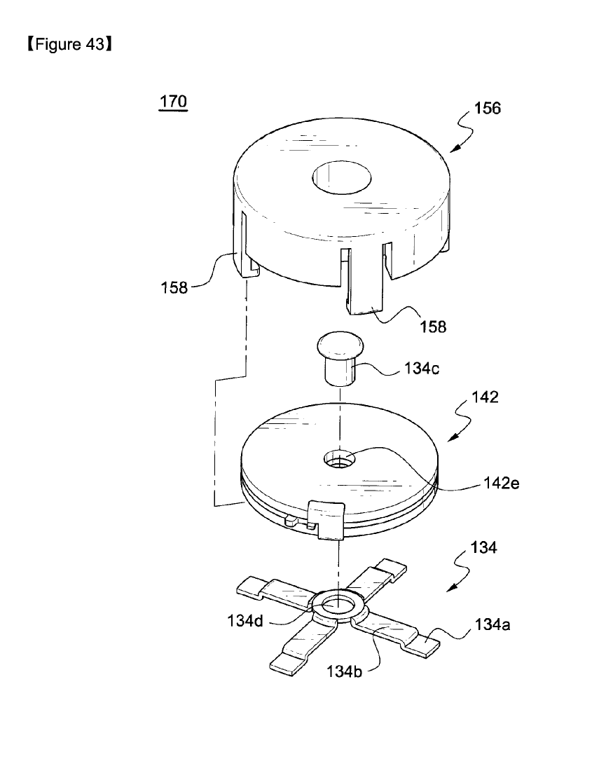

FIG. 43 is an exploded perspective view showing a fourth embodiment of the invention of a coin-type piezoelectric vibrator. In case of the piezoelectric vibrator (170) according to this embodiment, unlike the previous embodiment, the fastening member (148) is inelastic, and the vibration support member (134) has elasticity. The piezoelectric vibration member (142), the weight (146), and the fastening member (148) are same as the second embodiment of the coin-type piezoelectric vibrator shown in FIGS. 38 and 39. The vibration support member (134) is also same as the fourth embodiment of the square piezoelectric vibrator shown in FIGS. 32-34. The vibration support member (134) is combined to and supports the center of the piezoelectric vibration member (142), and the weight (156) is combined with the edge portions of the piezoelectric vibration member (142). Therefore, if the alternating operational voltage is applied, the piezoelectric vibration member (142) vibrates by repeating the shape of umbrella and the shape of flipped umbrella with the central portion as an acting point of vibration and the edge portion showing maximum displacement. The vibration is amplified by the weight (156) and transferred to the object to transfer vibration to through the vibration support member (134), such that the vibrational displacement gets amplified one more time.

### (5) Embodiment 3-5

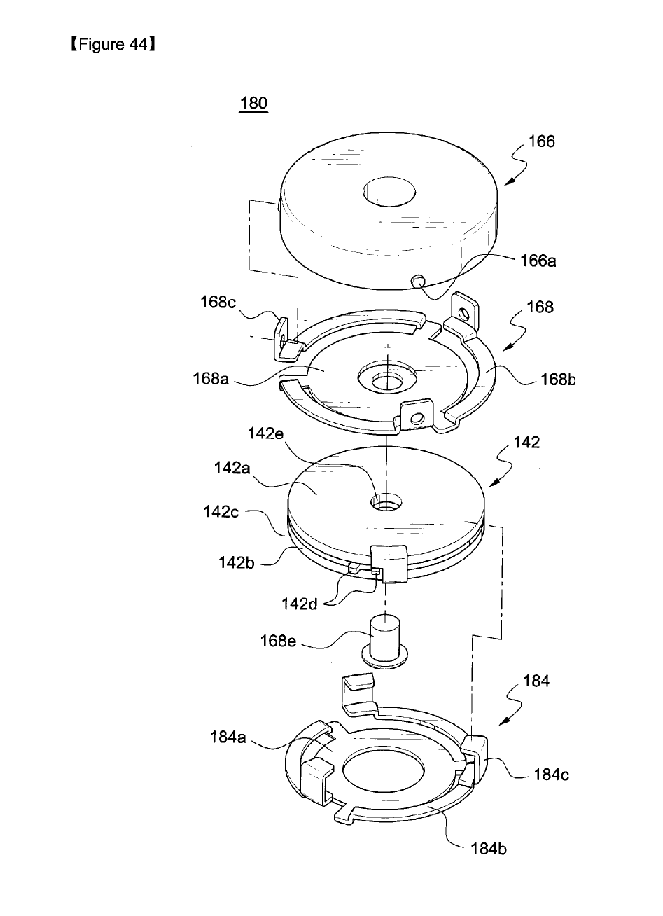

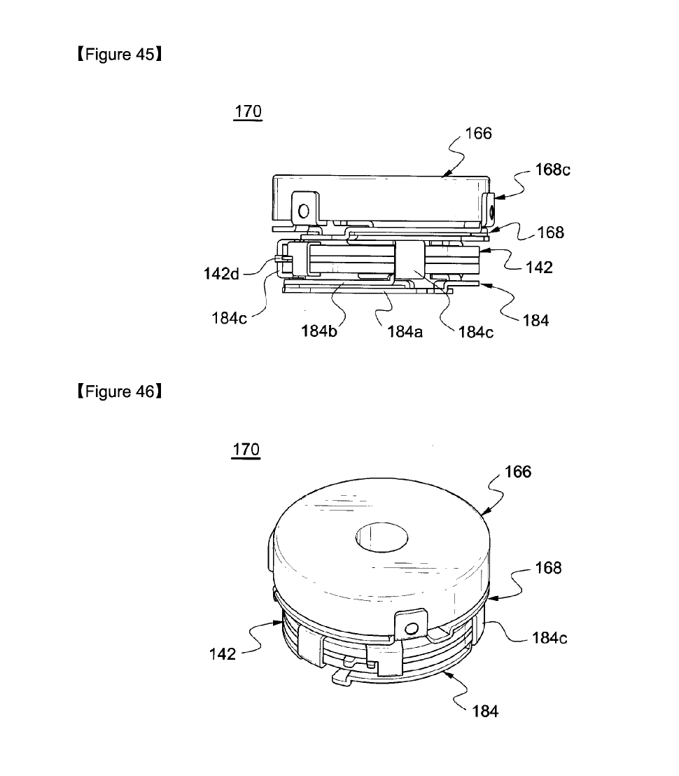

FIGS. 44 to 46 are an exploded perspective view and a front plan view and a perspective view of assembled state showing a fifth embodiment of the invention of a coin-type piezoelectric vibrator. The piezoelectric vibrator (180) adopts the piezoelectric vibration member (142), the weight (166), and the elastic fastening member (168), which are same as in the third embodiment of the coin-type piezoelectric vibrator shown in FIGS. 40-42. Therefore, the weight (166) is combined elastically to the center of the piezoelectric vibration member (142) through the elastic fastening member (168). The piezoelectric vibrator (180) employs a vibration support member (184). The vibration support member (184) comprises an approximately circular base portion (184a), three elastic arms (184b) extending circumferentially with a step upward from three locations of the edge portion, and fastening holders (184c) provided upward from the end of the elastic arms (184b). The edge portion of the piezoelectric vibration member (142) is inserted and engaged to the fastening holders (184c), and thereby the elastic vibration support member (184) supports elastically the edge portion of the piezoelectric vibration member (142). The piezoelectric vibrator (180) has elastic engagements between the piezoelectric vibration member (142) and the weight (166) and between the piezoelectric vibration member (142) and the vibration support member (184).

If an alternating operational voltage is applied, the piezoelectric vibration member (142) vibrates with the edge portion as an acting point of vibration, and the vibration goes through the amplification process receiving effects from the elasticity of the elastic vibration support member (184) and the elastic fastening member (168), which is transferred to the weight (166). And, due to the function of the weight (166), the vibrational power and displacement are amplified again. The amplified vibration by these processes is transferred to the object to transfer vibration to through the elastic vibration support member (184).

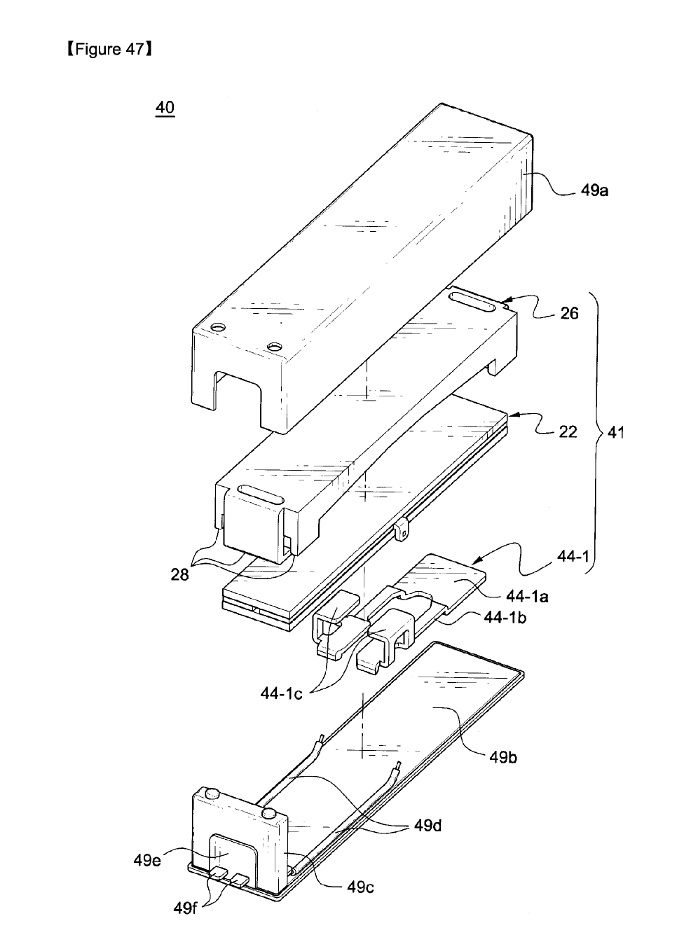

Even though various embodiments of piezoelectric vibrators are described in the above, the present invention is not limited to them, and may be varied based on the above description by a person having ordinary skill in the art to which the invention pertains. For example, in the case of the vibration support member (44) shown in FIG. 11, the fastening holder (44c) is supported by the set of ‘elastic bridge (44b)-fixing member (44a)’ on both sides stably, but due to the stable structure by the plurality of fixing portions, when a force pushing downward through the fastening holder (44c), the up-and-down displacement of the piezoelectric vibration member may be limited due to the strong resistance. In order to improve this, as shown in FIG. 47, one of the two sets of ‘elastic bridge (44b)-fixing member (44a)’ may be removed, such that the force resisting the force pushing down the fastening holder (44c) is weakened and the piezoelectric vibration member can generate larger vibration.

Also, even though the embodiments show the piezoelectric vibration member only as a bimorph type, they may be formed as a unimorph type. Also, the piezoelectric device layer may be formed in a single layer, or several or tens of layers.

Also, in addition to the method for generating vibration by applying an alternating operational voltage to the piezoelectric vibration member, there is a method for generating by supplying intermittently the voltage by repeated application and removal. By the former type of application, the asymmetrical piezoelectric vibration member such as rectangular piezoelectric vibration member vibrates by repeating the shape of bow and the shape of inverse bow, and the symmetrical piezoelectric vibration member such as square or coin-type piezoelectric vibration members vibrates by repeating the shape of umbrella and the shape of flipped umbrella alternatingly. By the latter type of application, the asymmetrical piezoelectric vibration member vibrates by repeating the shape of bow and the flat shape (the original, un-bent shape) alternatingly, and the symmetrical piezoelectric vibration member vibrates by repeating the shape of umbrella and the flat shape alternatingly.

On the other hand, the piezoelectric vibrators described in the above may be used as vibration means for a mouse, a remote, etc. as well as the mobile electronic devices such as a mobile phone, a game machine, etc. The piezoelectric vibrators may be applied to electrical/electronic devices which can supply electrical power for driving the piezoelectric vibrators. The piezoelectric vibrator may be installed as a form embedded in a housing or directly without any housing.

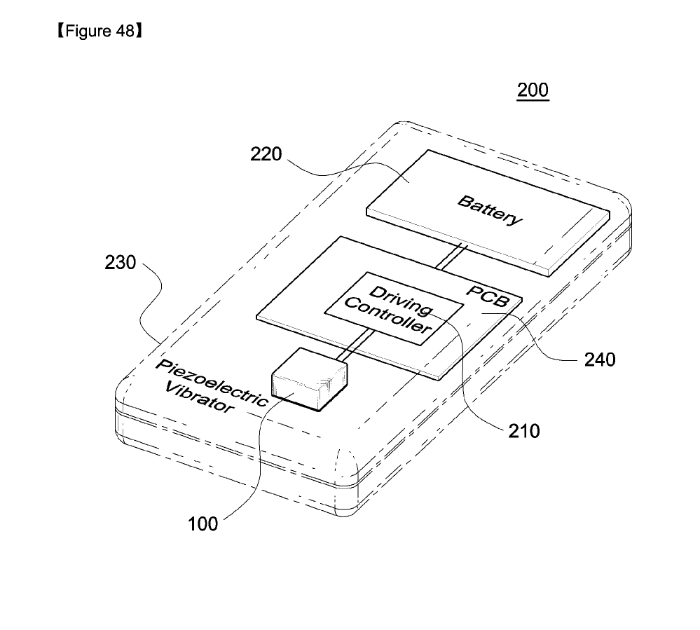

FIG. 48 is a diagram showing a case applying a piezoelectric vibrator module (100) to a mobile electronic device (200) as a vibration means. In order to use the piezoelectric vibrator module (100) as a vibration means, the mobile electronic device (200) comprises a body (230) in which the piezoelectric vibrator module (100) is installed, a battery (220) used for the operational power of the piezoelectric vibrator module (100), and a driving controller (210) which makes voltage for operating the piezoelectric vibrator module (100) to generate vibration using the battery (220) and supplies to the piezoelectric vibration member (102). The driving controller (210) has a function of converting the voltage of the battery (220) into the operational voltage of the piezoelectric vibration member (102), a function of controlling of supplying or closing of the power, etc. If the electrical/electronic devices with the piezoelectric vibrators use the regular commercial power instead of a battery, the driving controller (210) is configured to make the operational power for the piezoelectric vibrators from the commercial power source. Such circuits may be formed with processors or CPU, inverter circuit, etc. installed in the device (200), and they may be installed on a PCB board (240). Any piezoelectric vibrators described in the above may be used as vibration means.

### INDUSTRIAL APPLICABILITY

The piezoelectric vibrators disclosed by the present invention may be used widely as vibration means or alarm means of electrical/electronic devices such as mobile phones, pagers, portable multimedia players (PMPs), game machines, remote controllers, mouses, etc.

1. A piezoelectric vibrator comprising:
a piezoelectric vibration member generating vibration by change of applied voltage about a vibration acting point engaged to a vibration support member below;
a weight integrated monolithically with the piezoelectric vibration member, vibrating with the piezoelectric vibration member by the vibration of the piezoelectric vibration member, and amplifying power and displacement of the vibration; and
a vibration support member, whose one end being fixed to an object for delivering vibrational power and the other end engaging with a specific portion of the piezoelectric vibration member, for supporting the piezoelectric vibration member.

2. The piezoelectric vibrator of claim 1, wherein further comprising a fastening member for fastening the weight to the piezoelectric vibration member as one body.

3. The piezoelectric vibrator of claim 2, wherein the fastening member comprises an elastic fastening member for combining the weight and the piezoelectric vibration member elastically and amplifying the displacement of vibration of the piezoelectric vibration member.

4. The piezoelectric vibrator of claim 1, wherein the location where the weight engages with the piezoelectric vibration member is a portion where the piezoelectric vibration member gives a maximum up-and-down displacement (amplitude).

5. The piezoelectric vibrator of claim 1, wherein a first location where the vibration support member engages the piezoelectric vibration member and a second location where the weight engages the piezoelectric vibration member are any one selected from the following four locations: (a) the first location is both end portions of the piezoelectric vibration member in a direction of length, and the second location is a middle portion of the piezoelectric vibration member in a direction of length, (b) the first location is a middle portion of the piezoelectric vibration member in a direction of length, and the second location is both end portions of the piezoelectric vibration member in a direction of length, (c) the first location is a plurality of edge portions of the piezoelectric vibration member, and the second location is a central portion of the piezoelectric vibration member, and (d) the first location is a central portion of the piezoelectric vibration member, and the second location is a plurality of edge portions of the piezoelectric vibration member.

6. The piezoelectric vibrator of claim 5, wherein in the cases of (a) or (b), the piezoelectric vibration member vibrates bending in shapes of bow and reversed bow alternatingly or alternating between a shape of bow and a flat shape without bending, and in the cases of (c) and (d), the piezoelectric vibration member vibrates bending in shapes of umbrella and flipped umbrella alternatingly or alternating between a shape of umbrella and a flat shape without bending.

7. The piezoelectric vibrator of claim 1, wherein in a case that the weight is formed so as to have an area larger than the portion engaging with the piezoelectric vibration member, in the parts other than a portion engaging with the piezoelectric vibration member the weight is configured to stay away from the piezoelectric vibration member so as not to touch each other even during vibration.

8. The piezoelectric vibrator of claim 1, wherein the vibration support member is an elastic vibration support member supporting elastically the combined body of the piezoelectric vibration member and the weight and amplifying the vibration displacement of the combined body.

9. The piezoelectric vibrator of claim 1, further comprising a housing, which receives the combined body of the piezoelectric vibration member and the weight supported by the vibration support member, and has itself fixed to one end of the vibration support member so as to receive the amplified vibration through the vibration support member.

10. The piezoelectric vibrator of claim 1, wherein the vibration acting point of the piezoelectric vibration member engaging with and supported by the vibration support member is both end portions or a central portion of the piezoelectric vibration member in a direction of length when the piezoelectric vibration member is asymmetrical to have a length larger than a width, and an edge portion or a central portion of the piezoelectric vibration member when the piezoelectric vibration member is symmetrical like polygon or circle.

11. The piezoelectric vibrator of claim 1, wherein the piezoelectric vibration member comprises: a substrate; piezoelectric device layers formed by laminating a single or multiple layers of piezoelectric material on one or both surfaces of the substrate; and electrode layers for applying the voltage to top and bottom surfaces of the piezoelectric device layers.

12. The piezoelectric vibrator of claim 1, wherein the weight and the piezoelectric vibration member have a top-and-bottom relation, and are combined such that central points of both of them are aligned substantially.

13. A piezoelectric vibrator comprises:
a piezoelectric vibration member generating vibration with a vibration acting point engaging with a vibration support member as a reference by an applied alternating voltage or intermittently applied voltage;
a weight formed of material of high density and engaging with the piezoelectric vibration member, such that when the piezoelectric vibration member vibrates the weight loads its own weight at a specific portion where the displacement is largest;
a fastening member fastening the weight to a specific portion of the piezoelectric vibration member and transferring the vibration of the piezoelectric vibration member to the weight, such that the weight vibrates along; and
a vibration support member, whose one end is fixed to an object to which the vibration is delivered and the other end engaging with the vibration acting point of the piezoelectric vibration member and support,
wherein the weight, by the vibration of the piezoelectric vibration member, vibrates up-and-down in a same direction as the direction in which the vibration support member supports the piezoelectric vibration member so as to amplify power and displacement of the vibration, and the amplified vibration is transferred to the object through the vibration support member.

14. The piezoelectric vibrator of claim 13, wherein the location where the weight engages with the piezoelectric vibration member is a portion where the piezoelectric vibration member gives a maximum up-and-down displacement (amplitude).

15. The piezoelectric vibrator of claim 13, further comprising a housing, which receives the combined body of the piezoelectric vibration member and the weight supported by the vibration support member, and has itself fixed to one end of the vibration support member so as to receive the amplified vibration through the vibration support member.

16. The piezoelectric vibrator of claim 13, wherein the fastening member comprises an elastic fastening member for combining the weight and the piezoelectric vibration member elastically and amplifying the displacement of vibration of the piezoelectric vibration member.

17. The piezoelectric vibrator of claim 13, wherein the vibration support member is an elastic vibration support member supporting elastically the combined body of the piezoelectric vibration member and the weight and amplifying the vibration displacement of the combined body.

18. The piezoelectric vibrator of claim 13, wherein a first location where the vibration support member engages the piezoelectric vibration member and a second location where the weight engages the piezoelectric vibration member are any one selected from the following four locations: (a) the first location is both end portions of the piezoelectric vibration member in a direction of length, and the second location is a middle portion of the piezoelectric vibration member in a direction of length, (b) the first location is a middle portion of the piezoelectric vibration member in a direction of length, and the second location is both end portions of the piezoelectric vibration member in a direction of length, (c) the first location is a plurality of edge portions of the piezoelectric vibration member, and the second location is a central portion of the piezoelectric vibration member, and (d) the first location is a central portion of the piezoelectric vibration member, and the second location is a plurality of edge portions of the piezoelectric vibration member.

19. The piezoelectric vibrator of claim 18, wherein in the cases of (a) or (b), the piezoelectric vibration member vibrates bending in shapes of bow and reversed bow alternatingly or alternating between a shape of bow and a flat shape without bending, and in the cases of (c) and (d), the piezoelectric vibration member vibrates bending in shapes of umbrella and flipped umbrella alternatingly or alternating between a shape of umbrella and a flat shape without bending.

20. An electrical or electronic device comprising:
a body;
a power supply;
a piezoelectric vibrator installed in a specific location of the body and generating vibration, the piezoelectric vibrator being any one of the piezoelectric vibrators of claims 1-19; and
an operation controller for controlling the vibration of the piezoelectric vibration member by making the voltage needed by the piezoelectric vibrator in generating the vibration using voltage of the power supply and supplying the voltage to the piezoelectric vibrator.
